(19) United States
(12) Patent Application Publication
(10) Pub. No.: US 2012/0248634 A1
(43) Pub. Date: Oct. 4, 2012

(54) METHOD FOR MANUFACTURING FILM-LIKE ADHESIVE, ADHESIVE SHEET, SEMICONDUCTOR DEVICE, AND METHOD FOR MANUFACTURING SEMICONDUCTOR DEVICE

(76) Inventors: Kazuyuki Mitsukura, Tsukuba-shi (JP); Takashi Kawamori, Tsukuba-shi (JP); Takashi Masuko, Tsukuba-shi (JP); Shigeki Katogi, Tsukuba-shi (JP); Shinjiro Fujii, Hitachi-shi (JP)

(21) Appl. No.: 13/509,370

(22) PCT Filed: Nov. 10, 2010
(86) PCT No.: PCT/JP2010/070019

§ 371 Date: Jun. 22, 2012

(30) Foreign Application Priority Data
Nov. 13, 2009 (JP) 2009-260410
Nov. 13, 2009 (JP) 2009-260421
Jun. 17, 2010 (JP) 2010-138638

(51) Int. Cl. H01L 21/50; B05D 3/06; C09J 7/02; H01L 23/00

(52) U.S. Cl. 257/798; 438/118; 427/487; 428/345; 257/E23.002; 257/E21.499

(57) ABSTRACT

The method for manufacturing a film-like adhesive according to the present invention includes: applying an adhesive composition comprising (A) a radiation-polymerizable compound, (B) a photoinitiator and (C) a thermosetting resin, and having a solvent content of 5% by mass or lower and being liquid at 25° C., on a base material to thereby form an adhesive composition layer; and irradiating the adhesive composition layer with light to thereby form the film-like adhesive.

### TECHNICAL FIELD

The present invention relates to a method for manufacturing a film-like adhesive, an adhesive sheet, a semiconductor device, and a method for manufacturing a semiconductor device.

### BACKGROUND ART

Stacked package-type semiconductor devices in which a plurality of semiconductor elements are laminated in a multi-stage are used in applications including memories. In manufacture of semiconductor devices, in order to adhere semiconductor elements or semiconductor elements with a support member for mounting the semiconductor elements, film-like adhesives such as die attach films for semiconductors are applied (for example, see Patent Literature 1).

Die attach films for semiconductors are required to be excellent in hot fluidity so that embedding wires and filling up irregularities of substrates are sufficient. Then, a die attach film for a semiconductor aiming at improvement in hot fluidity is proposed (for example, see Patent Literature 2).

In flip chips, wafer-level CSPs and the like, although resin sealing is performed for protecting protrusions in packages having bumps and for filling between the protrusions, molding by a common solid epoxy resin sealing material is difficult. Thus, a sealing sheet obtained by molding a resin composition containing an epoxy resin and an inorganic filler, and a sealing film in which a high-molecular weight acryl polymer is blended are proposed (for example, see Patent Literatures 3 and 4).

### CITATION LIST

### Patent Literature

Patent Literature 1: Japanese Patent Application Laid-Open Publication No. 9-17810
Patent Literature 2: Japanese Patent Application Laid-Open Publication No. 2009-74067
Patent Literature 3: Japanese Patent Application Laid-Open Publication No. 8-73621
Patent Literature 4: Japanese Patent Application Laid-Open Publication No. 2005-60584

### SUMMARY OF INVENTION

### Technical Problem

The film-like adhesive as described above is fabricated by preparing a coating liquid in which an adhesive composition is dissolved or dispersed in a solvent, applying the coating liquid on a base material, and vaporizing the solvent by heating and drying. However, since the film-like adhesive of Patent Literature 2 cited above contains a large amount of a thermosetting component blended to impart hot fluidity, the crosslinking reaction partially progresses in heating and drying, posing the problem of spoiling hot fluidity.

The film-like sealing sheet of Patent Literature 3 cited above is fabricated by press working a composition containing a thermosetting resin and a filler. A sealing sheet obtained by such a method poses the problem of warping after thermosetting in a case where semiconductor packages and wafers are large. In order to suppress this, if a large amount of an inorganic filler such as silica is blended, in addition to a difficulty in collective coating, there arise the problem in which the flexibility of a film is damaged, causing a difficulty in takeup of the film and making the size elongation into a roll or the like impossible, the problem in which the handleability of the sheet decreases, and cracks are liable to occur during use, and the problem of spoiling the hot fluidity of the sealing sheet.

By contrast, a case where the film-like adhesive having a large thickness as described in Patent Literature 4 cited above is fabricated poses the problem of a high residual volatile content in heating and drying for vaporization of a solvent. If a low-boiling point solvent is used to reduce the residual volatile content, drying of the film surface progresses first, and the residual volatile content becomes much more. Therefore, the case of the above has the problem of a long time being necessary for solvent vaporization. If the drying time is made longer or the drying temperature is made higher, there further arises the problem in which the crosslinking reaction partially progresses in heating and drying, then spoiling the hot fluidity. In a method of the fabrication by laminating a thin film, there arise the problem of generating a lamination interface and decreasing the reliability, and a problem with manufacturing cost.

The present invention has been achieved in consideration of the above-mentioned situations, and an object thereof is to provide a method for manufacturing a film-like adhesive in which the film-like adhesive excellent in hot fluidity can be manufactured in a desired thickness in a shorter time than conventionally, and an adhesive sheet and a semiconductor device, and a method for manufacturing the semiconductor device.

### Solution to Problem

In order to solve the above-mentioned problems, the present invention provides a method for manufacturing a film-like adhesive, in which an adhesive composition containing (A) a radiation-polymerizable compound, (B) a photoinitiator and (C) a thermosetting resin, and having a solvent content of 5% by mass or lower and being liquid at 25° C. is applied on a base material to thereby form an adhesive composition layer, and the adhesive composition layer is irradiated with light to thereby form the film-like adhesive.

The solvent in the present invention refers to an organic compound having no radiation-polymerizable group such as an ethylenic unsaturated group, no thermal reactive group such as an oxime ester group, α-aminoacetophenone and phosphine oxide, and no thermoreactive group such as an epoxy group, a phenolic hydroxyl group, a carboxyl group, an amino group, an acid anhydride, an isocyanate, a peroxide, a diazo group, imidazole and an alkoxysilane, and having a molecular weight of 500 or lower and being liquid at room temperature (25° C.). Examples of such a solvent include dimethylformamide, toluene, benzene, xylene, methyl ethyl ketone, tetrahydrofuran, ethyl cellosolve, ethyl cellosolve acetate, dioxane, cyclohexanone, ethyl acetate, γ-butyrolactone and N-methyl-pyrrolidinone.

The method for manufacturing a film-like adhesive according to the present invention can manufacture the film-like adhesive excellent in hot fluidity in a desired thickness in a shorter time than conventionally. Since the film-like adhesive obtained is excellent in hot fluidity, the film-like adhesive can be thermocompression bonded well on an adherend.

According to the method for manufacturing a film-like adhesive according to the present invention, since use of the specific liquid adhesive composition described above needs no heating for solvent drying after the application, the thermal energy and volatile organic compounds (VOC) can be reduced, and further, occurrence of pinholes caused by thermal flow and volatile components can sufficiently be suppressed.

In the method for manufacturing a film-like adhesive according to the present invention, the (A) component is preferably liquid at 25° C. In this case, even in a composition containing no solvent, the viscosity can be reduced, and the adhesivity after curing can further be improved by blending a solid or high-viscosity thermosetting resin while the film formation is possible.

The (A) component preferably contains a monofunctional (meth)acrylate being liquid at 25° C. Here, the monofunctionality refers to having one carbon-carbon double bond in the molecule, and may have functional groups excluding the monofunctional group. Incorporation of the (meth)acrylate can further improve hot fluidity after light irradiation. The adhesivity can further be improved by blending a solid or high-viscosity thermosetting resin while the coatability is sufficiently maintained.

The monofunctional (meth)acrylate is more preferably one having an imide skeleton or a hydroxyl group. Thereby, the close contact and the adhesivity after curing of an obtained film-like adhesive laminated on an adherend can largely be improved.

In the method for manufacturing a film-like adhesive according to the present invention, the (B) component preferably contains a photoinitiator having a molecular extinction coefficient of 100 ml/g·cm or higher to light of a wavelength of 365 nm. Thereby, since the exposure amount when a film is made by light irradiation can be reduced, a film-like adhesive rendered into a B-stage in a shorter time is allowed to be obtained.

The molecular extinction coefficient can be determined by preparing a 0.001-mass % acetonitrile solution of a sample, putting the solution in a quartz cell, and measuring an extinction using a spectrophotometer (“U-3310” (trade name), made by Hitachi High-Technologies Corp.) at room temperature (25° C.) in the air.

The photoinitiator having a molecular extinction coefficient of 100 ml/g·cm or higher to light of a wavelength of 365 nm is preferably a compound having an oxime ester skeleton or a morpholine skeleton in the molecule. Incorporation of such a photoinitiator can reduce the tack force in a short time by light irradiation in the air without heating.

In the method for manufacturing a film-like adhesive according to the present invention, the adhesive composition can further contain (D) a curing agent.

In the method for manufacturing a film-like adhesive according to the present invention, the adhesive composition can further contain (E) a thermoradical generator. Thereby, since the (A) component which remains unreacted after light irradiation can be polymerized in thermosetting, foaming in the thermosetting and foaming and exfoliation in the thermal history thereafter of an obtained film-like adhesive can further be suppressed.

The present invention also provides an adhesive sheet having a structure in which a dicing sheet, and a film-like adhesive obtained by the method according to the present invention are laminated.

The adhesive sheet according to the present invention has advantages not only of the film-like adhesive being excellent in hot fluidity, but also of the adhesive sheet being manufactured easily. That is, the method for manufacturing a film-like adhesive according to the present invention can use as a base material a dicing sheet constituted of a heat-vulnerable material, for example, a flexible base material such as polyolefin, polyvinyl chloride or ethylene vinyl acetate (EVA). In this case, an adhesive sheet concurrently having the dicing function and the die bonding function can easily be manufactured in a short time.

In the adhesive sheet according to the present invention, the dicing sheet has a base material film and a radiation-curable pressure-sensitive adhesive layer provided on the base material film; and the adhesive sheet can have a structure in which a film-like adhesive is laminated with the radiation-curable pressure-sensitive adhesive layer. In such an adhesive sheet, the adhesive layer can easily be peeled off the base material film by an exposure treatment when diced semiconductors are picked up, or otherwise.

In the adhesive sheet according to the present invention, the dicing sheet may be composed only of a base material film. In this case, the manufacturing cost can be reduced more.

The present invention also provides a semiconductor device having a structure in which semiconductor elements and/or a semiconductor element and a support member for mounting the semiconductor element are adhered through a film-like adhesive obtained by the method according to the present invention.

In the semiconductor device according to the present invention, adhesion is carried out using a film-like adhesive according to the present invention which is excellent in hot fluidity, so that the semiconductor device can be made excellent in the reliability.

The present invention also provides a method for manufacturing a semiconductor device, which method comprises a step of pasting a film-like adhesive layer of the adhesive sheet according to the present invention on one surface of a semiconductor wafer, a step of cutting the semiconductor wafer along with the film-like adhesive layer to obtain a semiconductor element having the adhesive layer, and a step of compression bonding and thereby adhering the semiconductor element having the adhesive layer with another semiconductor element or a support member for mounting a semiconductor element, with the adhesive layer of the semiconductor element having the adhesive layer interposed therebetween.

According to the method for manufacturing a semiconductor device according to the present invention, since the adhesive sheet according to the present invention concurrently has the dicing function and the die bonding function, and the film-like adhesive is excellent in hot fluidity, a semiconductor device excellent in the reliability can be provided in a high manufacturing efficiency.

### Advantageous Effects of Invention

The present invention can provide a film-like adhesive excellent in hot fluidity which can be manufactured in a desired thickness in a shorter time than conventionally, and an adhesive sheet and a semiconductor device, and a method for manufacturing the semiconductor device.

### BRIEF DESCRIPTION OF DRAWINGS

FIG. 1 is an illustrative diagram showing one embodiment of the manufacturing method of a semiconductor device according to the present invention.

FIG. 2 is an illustrative diagram showing one embodiment of the manufacturing method of a semiconductor device according to the present invention.

FIG. 3 is an illustrative diagram showing one embodiment of the adhesive sheet according to the present invention.

FIG. 4 is an illustrative diagram showing another embodiment of the manufacturing method of a semiconductor device according to the present invention.

FIG. 5 is an illustrative diagram showing one embodiment of the manufacturing method of a semiconductor device according to the present invention.

FIG. 6 is an illustrative diagram showing one embodiment of the manufacturing method of a semiconductor device according to the present invention.

FIG. 7 is an illustrative diagram showing one embodiment of the manufacturing method of a semiconductor device according to the present invention.

FIG. 8 is an illustrative diagram showing one embodiment of the manufacturing method of a semiconductor device according to the present invention.

FIG. 9 is an illustrative diagram showing one embodiment of the manufacturing method of a semiconductor device according to the present invention.

FIG. 10 is an illustrative diagram showing one embodiment of the manufacturing method of a semiconductor device according to the present invention.

FIG. 11 is an illustrative diagram showing one embodiment of the manufacturing method of a semiconductor device according to the present invention.

### DESCRIPTION OF EMBODIMENTS

Hereinafter, preferred embodiments according to the present invention will be described in detail. However, the present invention is not limited to the following embodiments.

Hereinafter, embodiments according to the present invention will be described, as required, by reference to the drawings. However, the present invention is not limited to the following embodiments. In the drawings, the same reference sign is affixed to the same element, and duplicate description will be omitted. The positional relationship vertical, horizontal and otherwise is based on the positional relationship shown in the drawings unless otherwise described, and the dimensional ratios of the drawings are not limited to the ratios shown therein.

The method for manufacturing a film-like adhesive according to the present invention comprises: applying an adhesive composition containing (A) a radiation-polymerizable compound, (B) a photoinitiator and (C) a thermosetting resin, and having a solvent content of 5% by mass or lower and being liquid at 25° C., on a base material to thereby form an adhesive composition layer; and irradiating the adhesive composition layer with light to thereby form the film-like adhesive.

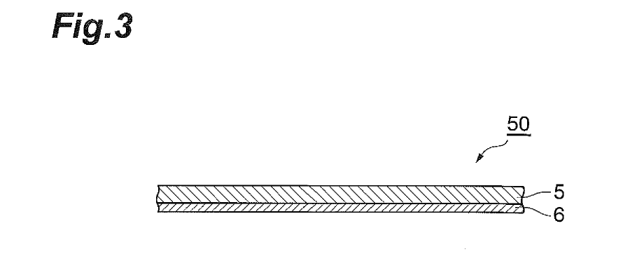

FIG. 3 is an illustrative diagram showing one embodiment of the adhesive sheet according to the present invention. An adhesive sheet 50 shown in FIG. 3 has a structure in which a film-like adhesive 5 formed by the manufacturing method of a film-like adhesive according to the present invention is laminated on a base material 6.

A method for fabricating an adhesive composition includes one in which (A) a radiation-polymerizable compound, (B) a photoinitiator, (C) a thermosetting resin and other blending components are added, and thereafter stirred and defoamed. In the present embodiment, the (A) component is preferably liquid at room temperature (25° C.). At this time, in a case where the solubilities of (B) the photoinitiator, (C) the thermosetting resin and the other blending components to the (A) component are poor, stirring is preferably carried out under heating at 100° C. or lower. This means can reduce the residual solid content. Stirring of the adhesive composition is preferably carried out in a light-shielded room or a yellow room. In a case where a thermosetting agent such as imidazole or a thermoradical initiator is blended, stirring is preferably carried out at 40° C. or lower. In a case where the solubility of a curing accelerator such as imidazoles to the other components is poor, the curing accelerator can previously be dispersed or dissolved in the (A) component using a dispersing machine.

An adhesive composition obtained is preferably shielded from light, and preferably stored at 0° C. or lower, and more preferably stored at −20° C. or lower. In order to improve the preservation stability, oxygen or air may be bubbled or enclosed.

Examples of the base material include a polyester film, a polypropylene film, a polyethylene terephthalate film, a polyimide film, a polyetherimide film, a polyether naphthalate film and a methylpentene film. These films as a base material may be combined in two or more to make a multilayer film, and may be ones whose surface is treated with a silicone-, silica- or otherwise-based release agent or the like.

A method for applying an adhesive composition on a base material is not especially limited, but spray coat, curtain coat, bar coat, knife coat and the like can be used. In order to decrease the viscosity of the adhesive composition, heating at 100° C. or lower may be carried out.

The thickness of a coating film can suitably be set according to applications of the film-like adhesive. The present invention allows making the film thickness large, different from manufacture using solvent vaporization. In applications of sealing films and stress-relaxing films, the thickness of a coating film is preferably set such that the thickness of a film-like adhesive becomes 50 to 200 μm. The film thickness of a film-like adhesive can be measured using a surface roughness tester (made by Kosaka Laboratory Ltd.).

In the method for manufacturing a film-like adhesive according to the present invention, irradiation of an adhesive composition layer with light causes (A) a radiation-polymerizable compound to react to form a film-like adhesive. Examples of the reaction carried out here include addition reaction, polymerization reaction, transfer reaction, cyclization reaction and dimerization reaction; and crosslinking reaction and polymerization reaction are preferable from a viewpoint where film formation is possible in a low energy, and the polymerization reaction is more preferable from a viewpoint where tack reduction can be achieved in a lower exposure amount.

Examples of light irradiation to an applied adhesive composition include irradiations of ionizing radiation and non-ionizing radiation, and specific examples thereof include irradiations with excimer laser light using ArF, KrF or the like, electron beams, extreme ultraviolet rays, vacuum ultraviolet light, X rays, ion beams, and ultraviolet rays such as i line and g line. In the case of ultraviolet irradiation, the light irradiation can be carried out in the air, in nitrogen, or under vacuum.

Light irradiation is preferably carried out right after the application of an adhesive in order to prevent occurrence of pinholes and the like. Light irradiation can be carried out in the air, in nitrogen or under vacuum, and after lamination of another base material (cover film). A cover film can be laminated after light irradiation in the air, and light irradiation can be carried out again. The light reirradiation can more reduce the tackness after the exposure.

Heating may be carried out after light irradiation. Thereby, a reaction by the light irradiation progresses and tackness is likely to be reduced. The heating can be carried out on a hot plate or in a furnace. The heating temperature is preferably 120° C. or lower, more preferably 100° C. or lower, and most preferably 80° C. or lower, from the viewpoint of decreases in fluidity and adhesivity due to the progress of the curing reaction.

The adhesive composition used in the present invention will be described more in detail.

The adhesive composition is of a non-solvent type having a solvent content of 5% by mass or lower, but the content of a solvent is preferably 1% by mass or lower.

Examples of an (A) component used in the present invention include compounds having an ethylenic unsaturated group. The ethylenic unsaturated group includes a vinyl group, an allyl group, a propargyl group, a butenyl group, an ethynyl group, a phenylethynyl group, a maleimide group, a nadiimido group and a (meth)acryl group. A (meth)acryl group is preferable from the viewpoint of the reactivity.

The (A) component is preferably liquid at room temperature (25° C.) in order that an adhesive composition is applied without using any solvent. The viscosity at room temperature is preferably 30,000 mPa·s or lower, more preferably 20,000 mPa·s, and most preferably 10,000 mPa·s. If the viscosity exceeds 30,000 mPa·s, the viscosity of the adhesive composition rises to cause the fabrication of a vanish to be likely to become difficult, and the film thickness reduction and the discharge are likely to become difficult.

The viscosity at room temperature in the present description refers to a measurement value at 25° C. by an E-type viscometer.

In the adhesive composition according to the present invention, the (A) component preferably contains (A1) a monofunctional (meth)acrylate (hereinafter, referred to as an A1 compound in some cases). The monofunctionality used here refers to having one carbon-carbon double bond in the molecule, and may have other functional groups. Addition of a monofunctional (meth)acrylate can particularly reduce the crosslinking density in exposure for film making, and can make the thermocompression bondability, the low stress and the adhesivity after the exposure in good states.

A monofunctional (meth)acrylate exhibit preferably a 5%-weight loss temperature of 100° C. or higher, more preferably 120° C. or higher, still more preferably 150° C. or higher, and most preferably 180° C. or higher. Since the material design placing organic compounds as main ingredients is preferable from the viewpoint of the viscosity reduction of an adhesive composition, and the suppression of surface irregularities after application and the hot fluidity after film making, the monofunctional (meth)acrylate preferably has a 5%-weight loss temperature of 500° C. or lower. The 5%-weight loss temperature of a monofunctional (meth)acrylate is measured using a simultaneous thermogravimetric/differential thermal analyzer (TG/DTA6300, made by SII Nano Technology Inc.) at temperature-rise rate of 10° C./min in a nitrogen flow (400 ml/min).

Blending of a monofunctional (meth)acrylate exhibiting a 5%-weight loss temperature in the range of the temperature described above can suppress the vaporization of the unreacted monofunctional (meth)acrylate remaining after film making by exposure, in thermocompression bonding or thermosetting.

In the case of a photosensitive composition in which a compound having two or more carbon-carbon double bonds in the molecule is blended, the composition turns into a state of a crosslinking structure being formed on light irradiation; so, since the composition hardly melts in a hot time thereafter and hardly develops tackness, the composition is likely to be difficult to thermocompression bond. By contrast, in a case where a compound having one carbon-carbon double bond in the molecule like the monofunctional (meth)acrylate is blended, the hot fluidity can be improved. Since the molecular weight of (A1) a monofunctional (meth)acrylate after light irradiation becomes several hundred thousands or more, in a case where the hot fluidity is highly demanded, (A1) the monofunctional (meth)acrylate is preferably used singly. For the purpose of heat resistance and the reduction of the tack strength after exposure, a compound having two or more carbon-carbon double bonds in the molecule may be used concurrently in 0.1 to 50% by mass with respect to (A1) the monofunctional (meth)acrylate.

Examples of the monofunctional (meth)acrylate include: from the viewpoint of being capable of making cured products toughened, preferably glycidyl group-containing (meth)acrylates, phenolic hydroxyl group-containing (meth)acrylates such as 4-hydroxyphenyl methacrylate and 3,5-dimethyl-4-hydroxybenzylacrylamide, and carboxyl group-containing (meth)acrylates such as 2-methacryloyloxyethyl phthalate, 2-methacryloyloxypropyl hexahydrophthalate and 2-methacryloyloxymethyl hexahydrophthalate; from the viewpoint of being capable of improving heat resistance, preferably aromatic-containing (meth)acrylates such as phenol EO-modified (meth)acrylates, phenol PO-modified (meth)acrylates, nonylphenol EO-modified (meth)acrylates, nonylphenol PO-modified (meth)acrylates, phenoxyethyl (meth)acrylate, phenoxyethylene glycol (meth)acrylate, phenoxydiethylene glycol (meth)acrylate, hydroxyethylated phenylphenol acrylates, phenoxypolyethylene glycol (meth)acrylate, nonylphenoxyethylene glycol (meth)acrylate, nonylphenoxypolyethylene glycol (meth)acrylates, nonylphenoxypolypropylene glycol (meth)acrylates, benzyl (meth)acrylate, 2-methacryloyloxyethyl 2-hydroxypropylphthalate and phenylphenol glycidyl ether acrylate; from the viewpoint of being capable of imparting the close contact after film making and the adhesivity after thermosetting, preferably hydroxyl group-containing (meth)acrylates represented by the following formula (A-1) or (A-2) such as 2-hydroxy-3-phenoxypropyl (meth)acrylate, o-phenylphenol glycidyl ether (meth)acrylate, 2-(meth)acryloyloxy-2-hydroxypropyl phthalate, 2-(meth)acryloyloxyethyl-2-hydroxyethyl-phthalic acid and 2-hydroxy-3-phenoxypropyl (meth)acrylate, and imide group-containing (meth)acrylates represented by the following formula (A-3) or (A-4) such as 2-(1,2-cyclohexacarboxylmide)ethyl acrylate; and from the viewpoint of being capable of making an adhesive composition of a low viscosity, preferably isoboronyl-containing (meth)acrylates, dicyclopentadienyl group-containing (meth)acrylates and isoboronyl (meth)acrylate.

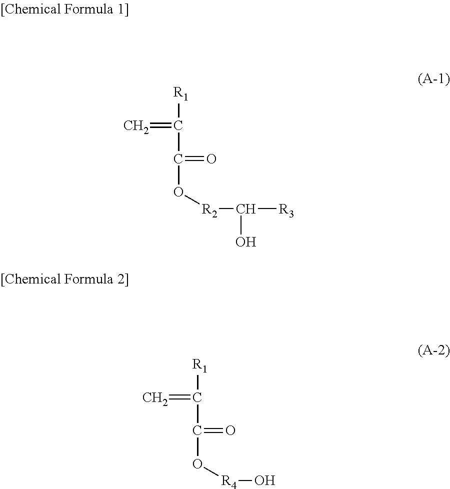

In the formulae (A-1) and (A-2), R₁ denotes a hydrogen atom or a methyl group; R₃ denotes a monovalent organic group; and R₂ and R₄ each denote a divalent organic group. R₃ preferably has an aromatic group from the viewpoint of heat resistance. R₄ preferably has an aromatic group from the viewpoint of heat resistance.

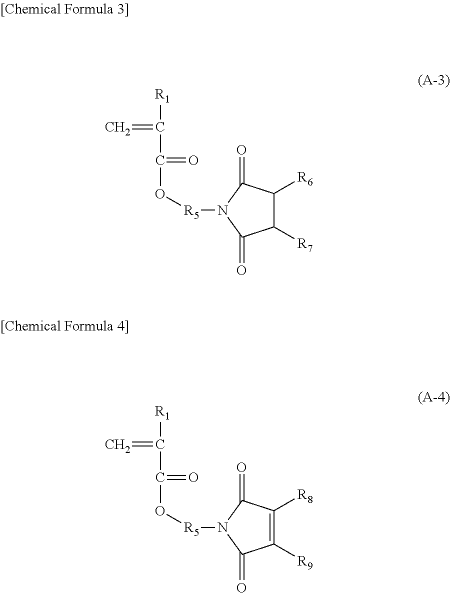

In the formulae (A-3) and (A-4), R₁ denotes a hydrogen atom or a methyl group; R₅ denotes a divalent organic group; R₆, R₇, R₈ and R₉ each denote a monovalent hydrocarbon group having 1 to 30 carbon atoms; and R₆ and R₇ may bond with each other to form a ring, and R₈ and R₉ may bond with each other to form a ring. In a case where R₆ and R₇, and R₈ and R₉ each form a ring, examples of the ring include a benzene ring structure and an alicyclic structure. The benzene ring structure and the alicyclic structure may have a thermosetting group such as a carboxyl group, a phenolic hydroxyl group or an epoxy group, or may have an organic group such as an alkyl group.

Compounds represented by the above formulae (A-3) and (A-4) can be synthesized, for example, by reacting an N-hydroxyalkylimide compound obtained by reacting a monofunctional acid anhydride with ethanol amine, with an acrylate ester or an acrylate ester by a well-known method. In this case, as the monofunctional acid anhydrides, dicarboxylic anhydrides including 4-phenylethynylphthalic anhydride, phthalic anhydride, maleic anhydride, succinic anhydride, 5-norbornene-2,3-dicarboxylic anhydride, 2,5-norbornadiene-2,3-dicarboxylic anhydride, maleic acid anhydride, trimellitic anhydride, cyclohexanedicarboxylic anhydride, 5-norbornene-2,3-dicarboxylic anhydride, cis-norbornene-endo-2,3-dicarboxylic hexahydrophthalic anhydride, hexahydrophthalic anhydride, 1,2,3,6-tetrahydrophthalic anhydride and 3,4,5,6-tetrahydrophthalic anhydride can be used. Examples of the N-hydroxyalkylimide compound include N-hydroxyethylphthalimide and N-hydroxyethylsuccinimide.

As compounds represented by the above formulae (A-3) and (A-4), compounds represented by the following formulae (A-5) to (A-9) are preferably used from the viewpoint of the preservation stability, the low tackness after film making, the close contact after film making and the heat resistance, adhesivity and reliability after thermosetting, and compounds represented by the following formulae (A-5), and (A-7) to (A-9) are more preferably used from the viewpoint of the low viscosity.

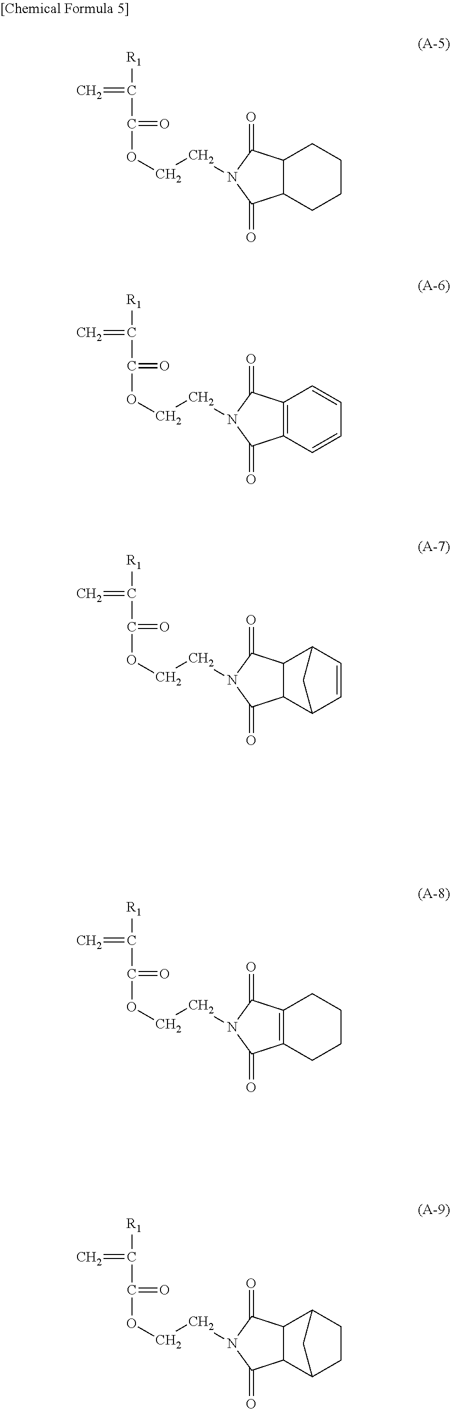

In the above formulae (A-5) to (A-9), R₁ denotes a hydrogen atom or a methyl group.

The monofunctional (meth)acrylate preferably has one of a urethane group, an isocyanuric group, an imide group, a phenolic hydroxyl group and a hydroxyl group, and is especially preferably a monofunctional (meth)acrylate having an imide group or a hydroxyl group in the molecule, from the viewpoint of the close contact with an adherend after film making, the adhesivity after curing, and the heat resistance.

A monofunctional (meth)acrylate having an epoxy group can also be used preferably. From the viewpoint of the preservation stability, the adhesivity, the low outgass of packages during assembling and heating and after assembling, and the heat resistance and moisture resistance, the monofunctional (meth)acrylate exhibits a 5%-weight loss temperature of preferably 150° C. or higher from the viewpoint of being capable of suppressing vaporization or segregation to the surface by heating and drying on film formation, more preferably 180° C. or higher and still more preferably 200° C. or higher from the viewpoint of being capable of suppressing voids, exfoliation and a decrease in the adhesivity due to outgas during thermosetting, and most preferably 260° C. or higher from the viewpoint of being capable of suppressing voids and exfoliation due to vaporization of unreacted components in reflow. Such a monofunctional (meth)acrylate having an epoxy group can satisfy the heat resistance by using as a raw material a polyfunctional epoxy resin exhibiting a 5%-weight loss temperature of 150° C. or higher.

Examples of the monofunctional (meth)acrylate having an epoxy group include glycidyl methacrylate, glycidyl acrylate, 4-hydroxybutyl acrylate glycidyl ether and 4-hydroxybutyl methacrylate glycidyl ether, and additionally, compounds obtained by reacting a compound having a functional group reactive with an epoxy group and an ethylenic unsaturated group with a polyfunctional epoxy resin. The functional group reactive with an epoxy group is not especially limited, but examples thereof include an isocyanate group, a carboxyl group, a phenolic hydroxyl group, a hydroxyl group, an acid anhydride, an amino group, a thiol group and an amide group. These compounds can be used singly or in combinations of two or more. More specifically, for example, a compound can be obtained by reacting a polyfunctional epoxy resin having two or more epoxy groups in one molecule thereof with (meth)acrylic acid of 0.1 to 0.9 equivalent weight with respect to one equivalent weight of the epoxy groups in the presence of triphenylphosphine or tetrabutylammonium bromide. A glycidyl group-containing urethane (meth)acrylate or the like can be obtained by reacting a polyfunctional isocyanate compound with a hydroxyl group-containing (meth)acrylate and a hydroxyl group-containing epoxy compound, or a polyfunctional epoxy resin with an isocyanate group-containing (meth)acrylate, in the presence of dibutyltin dilaurate.

Further as a monofunctional (meth)acrylate having an epoxy group, use of a high-purity product thereof is preferable in which alkaline metal ions, alkaline earth metal ions and halogen ions, especially chlorine ions, hydrolyzable chlorine and the like, as impurity ions, are decreased to 1,000 ppm or less, from the viewpoint of prevention of electromigration and corrosion-proofing of metal conductor circuits. For example, use as a raw material of a polyfunctional epoxy resin decreased in alkaline metal ions, alkaline earth metal ions, halogen ions and the like can satisfy the impurity ion concentration described above. The total chlorine content can be measured according to JIS K7243-3.

A monofunctional (meth)acrylate component having an epoxy group, which satisfies the heat resistance and the purity, is not especially limited, but includes ones using as a raw material glycidyl ethers of bisphenol A (or AD, S, or F), glycidyl ethers of hydrogenated bisphenol A, glycidyl ethers of an ethylene oxide adduct of bisphenol A and/or F, glycidyl ethers of a propylene oxide adduct of bisphenol A and/or F, glycidyl ethers of a phenol novolac resin, glycidyl ethers of a cresol novolac resin, glycidyl ethers of a bisphenol A novolac resin, glycidyl ethers of a naphthalene resin, trifunctional (or tetrafunctional) glycidyl ethers, glycidyl ethers of a dicyclopentadiene phenol resin, glycidyl esters of a dimer acid, trifunctional (or tetrafunctional) glycidylamines, glycidylamines of a naphthalene resin, and the like.

Particularly in order to improve the thermocompression bondability, the low stress property and the adhesivity, the number of the epoxy group is preferably 3 or less. Such a compound is not especially limited, but a compound or the like is preferably used which is represented by the following formula (A-10), (A-11), (A-12), (A-13) or (A-14). In the following formulae (A-10) to (A-14), R¹² and R¹⁶ denote a hydrogen atom or a methyl group; and R¹⁰, R¹¹, R¹³ and R¹⁴ denote a divalent organic group. R¹⁵ is an organic group having an epoxy group; one of R¹⁷ and R¹⁸ is an organic group having an ethylenic unsaturated group, and the other is an organic group having an epoxy group. f in (A-13) denotes an integer of 0 to 3.

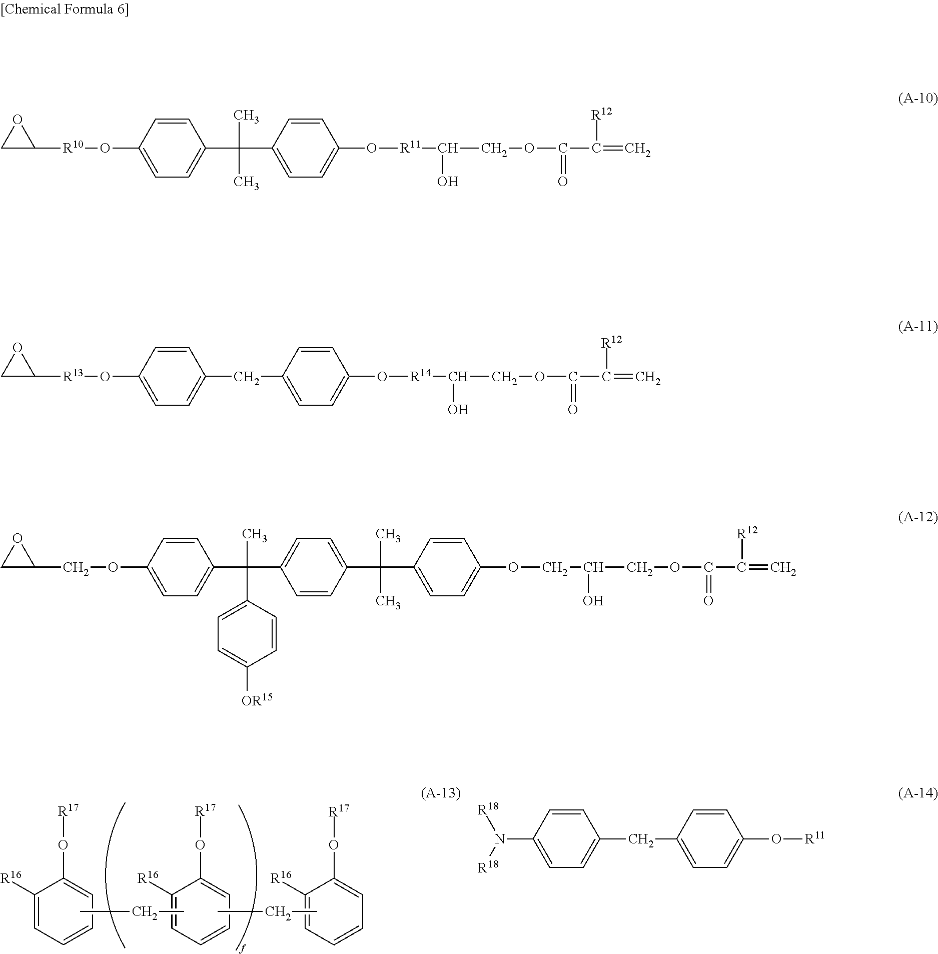

The content of the monofunctional (meth)acrylate is preferably 20 to 100% by mass, more preferably 40 to 100% by mass, and most preferably 50 to 100% by mass, with respect to the total amount of an (A) component. Making the blend amount of a monofunctional (meth)acrylate in the range of the above can improve the close contact and thermocompression bondability with an adherend after film making.

The A1 compound has a viscosity at 25° C. of preferably 5,000 mPa·s or lower from the viewpoint of the solubilities of other components such as the (B) component and the (C) component, more preferably 3,000 mPa·s or lower and still more preferably 2,000 mPa·s or lower from the viewpoint of the film thickness reduction, and most preferably 1,000 mPa·s or lower from the viewpoint of improving the adhesivity by blending a large amount of a solid or high-viscosity thermosetting resin. The viscosity used here refers to a value for the A1 compound, and is a viscosity value measured using an EHD-type rotary viscometer, made by Tokyo Keiki Inc., at 25° C.

If the viscosity of the A1 compound exceeds 5,000 mPa·s, the viscosity of an adhesive composition increases, whereby the film thickness reduction is likely to become difficult, and the coating is likely to become difficult. The viscosity at 25° C. of an A1 compound is preferably 10 mPa·s or higher from the viewpoint of preventing occurrence of pinholes in application and securing the heat resistance.

The viscosity of an A1 compound is preferably 1,000 mPa·s or lower from the viewpoint of improving the dischageability when an adhesive composition is discharged from a nozzle or the like, and the film thickness reduction, and is preferably 5 mPa·s or higher from the viewpoint of decreasing the outgas.

The A1 compound exhibits a 5%-weight loss temperature of preferably 100° C. or higher, more preferably 120° C. or higher, still more preferably 150° C. or higher, and most preferably 180° C. or higher. The 5%-weight loss temperature used here refers to a 5%-weight loss temperature when the A1 compound is measured using a simultaneous thermogavimetric/differential thermal analyzer (TG/DTA6300, made by SII Nano Technology Inc.) at a temperature-rise rate of 10° C./min in a nitrogen flow (400 ml/min).

Since the material design placing organic compounds as main ingredients is preferable from the viewpoint of making the viscosity of an adhesive composition low, suppressing the surface irregulalities after coating, and the hot fluidity after film making, the 5%-weight loss temperature of the A1 compound is preferably 500° C. or lower.

Further with respect to an A1 compound, a polymer obtained by polymerizing the A1 compound preferably has a Tg of 100° C. or lower from the viewpoint of the low-temperature thermocompression bondability and the hot fluidity after film making, and preferably has a Tg of 20° C. or higher from the viewpoint of the pickup property after film making. The Tg of a polymer of an A1 compound is a tan δ peak temperature in 150° C. to 200° C. as measured using a viscoelastometer (trade name: ARES, made by Rheometrics Scientific F.E. Ltd.) for a laminate prepared by laminating coating films so that the film-laminate thickness becomes 150 μm, the coating films each being obtained by applying a composition in which a photoinitiator I-379EG (made by Ciba Japan K.K.) is dissolved in a proportion of 3% by mass to the A1 compound in the A1 compound on a PET (polyethylene terephthalate) film so that the coating film thickness becomes 30 μm, and being exposed to 1,000 mJ/cm² using a high-precision exposure machine (trade name: EXM-1172-B-∞, made by ORC Manufacturing Co., Ltd.). Measurement plates used in the viscoelasticity measurement are parallel plates of 8 mm in diameter, and measurement conditions are set at a temperature-rise rate of PC/min, measurement temperatures of −50° C. to 200° C., and a frequency of 1 Hz.

The adhesive composition according to the present invention may contain a di- or more polyfunctional (meth)acrylate other than the A1 compound as (A) the radiation-polymerizable compound. The di- or more polyfunctionality used here refers to having two or more carbon-carbon double bonds in one molecule. Such an acrylate is not especially limited, but includes diethylene glycol diacrylate, triethylene glycol diacrylate, tetraethylene glycol diacrylate, diethylene glycol dimethacrylate, triethylene glycol dimethacrylate, tetraethylene glycol dimethacrylate, trimethylolpropane diacrylate, trimethylolpropane triacrylate, trimethylolpropane dimethacrylate, trimethylolpropane trimethacrylate, 1,4-butanediol diacrylate, 1,6-hexanediol diacrylate, 1,4-butanediol dimethacrylate, 1,6-hexanediol dimethacrylate, pentaerythritol triacrylate, pentaerythritol tetraacrylate, pentaerythritol trimethacrylate, pentaerythritol tetramethacrylate, dipentaerythritol hexaacrylate, dipentaerythritol hexamethacrylate, styrene, divinylbenzene, 4-vinyltoluene, 4-vinylpyridine, N-vinylpyrrolidone, 2-hydroxyethyl acrylate, 2-hydroxyethyl methacrylate, 1,3-acryloyloxy-2-hydroxypropane, 1,2-methacryloyloxy-2-hydroxypropane, methylenebisacrylamide, N,N-dimethylacrylamide, N-methylolacrylamide, triacrylate of tris(β-hydroxyethyl)isocyanurate, a compound represented by the following formula (A-15), urethane acrylate or urethane methacrylate, and urea acrylate.

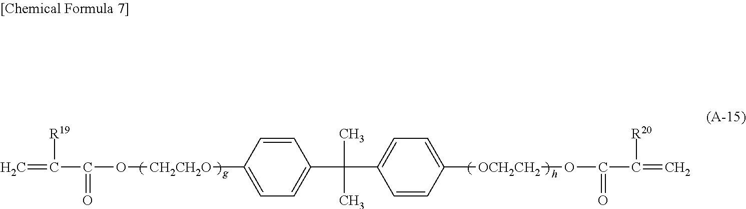

In the above formula (A-15), R¹⁹ and R²⁰ each independently denote a hydrogen atom or a methyl group; and g and h each independently denote an integer of 1 to 20.

The di- or more polyfunctional (meth)acrylate also includes a compound in which R¹⁵ in the above formula (A-12) is an organic group having an ethylenic unsaturated group, a compound in which two or more of R¹⁷ in the above formula (A-13) are each an organic group having an ethylenic unsaturated group and the rest ones thereof are each an organic group having an epoxy group, and a compound in which two or more of R¹⁸ in the above formula (A-14) are each an organic group having an ethylenic unsaturated group and the rest ones thereof are each an organic group having an epoxy group.

The radiation-polymerizable compound can be used singly or in combinations of two or more. Above all, a radiation-polymerizable compound having a glycol skeleton represented by the above formula (A-15) is preferable from the viewpoint of being capable of sufficiently imparting the solvent resistance after curing; and urethane acrylate and methacrylate, and isocyanuric acid di- or triacrylate and di- or trimethacrylate are preferable from the viewpoint of being capable of sufficiently imparting high adhesivity after curing.

The adhesive composition according to the present invention preferably contains a tri- or more polyfunctional acrylate compound. This case can more improve the adhesivity after curing, and suppress the outgas on heating.

The adhesive composition according to the present invention preferably contains an isocyanuric acid ethylene oxide-modified di- and triacrylate from the viewpoint of being capable of sufficiently imparting the heat resistance after curing.

The adhesive composition according to the present invention can contain a monofunctional maleimide compound represented by the following structural formula for the purpose of reducing the tackness and improving the adhesivity after exposure.

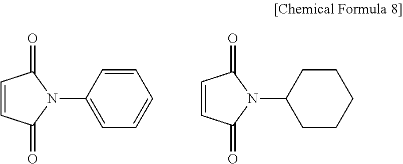

Use of a radiation-polymerizable compound having a high functional group equivalent weight allows lowering the stress and lowering the warp. The radiation-polymerizable compound having a high functional group equivalent weight preferably has a polymerizable functional group equivalent weight of 200 eq/g or higher, more preferably 300 eq/g or higher, and most preferably 400 eq/g or higher. Use of a radiation-polymerizable compound having a polymerizable functional group equivalent weight of 200 eq/g or higher and having an ether skeleton, a urethane group and/or an isocyanuric group allows improving the adhesivity of an adhesive composition. A radiation-polymerizable compound having a polymerizable functional group equivalent weight of 200 eq/g or higher and a radiation-polymerizable compound having a polymerizable functional group equivalent weight of 200 eq/g or lower may be concurrently used. In this case, as the radiation-polymerizable compound, a radiation-polymerizable compound having a urethane group and/or an isocyanuric group is preferably used.

The (A) component preferably exhibits a 5%-weight loss temperature of 120° C. or higher, more preferably 150° C. or higher, and still more preferably 180° C. or higher. The 5%-weight loss temperature used here refers to a value for the total of the (A) component contained in an adhesive composition, and is a 5%-weight loss temperature when the (A) component is measured using a simultaneous thermogravimetric/differential thermal analyzer (TG/DTA6300, made by SII Nano Technology Inc.) at temperature-rise rate of 10° C./min in a nitrogen flow (400 ml/min). Application of a radiation-polymerizable compound having a high 5%-weight loss temperature as described above can suppress vaporization of the unreacted radiation-polymerizable compound in thermocompression bonding or thermosetting.

The content of an (A) component is preferably 10 to 95% by mass, more preferably 20 to 90% by mass, and most preferably 40 to 90% by mass, with respect to the total amount of an adhesive composition. If the content of the (A) component is less than 10% by mass, the surface tack force after exposure is likely to become large, and if that exceeds 95% by mass, the adhesive strength after thermosetting is likely to decrease, which are not preferable.

The adhesive composition according to the present invention preferably contains a polymer of the (A) component having a molecular weight of 50,000 to 1,000,000 when being irradiated with light, from the viewpoint of making sufficiently excellent the high-temperature adhesivity, the film handleability such as bleeding in roll processing, and the pressure-sensitive adhesivity in laminating.

Further from the viewpoint of more improving the hot fluidity, a polymer of the (A) component having a molecular weight of 1,000 to 500,000 when being irradiated with light is preferably contained.

The molecular weight of the polymer described above refers to a weight-average molecular weight thereof when an adhesive film is dissolved in dimethylformamide, and measured in terms of polystyrene using a high-performance liquid chromatography “C-R4A” (trade name), made by Shimadzu Corp., the adhesive film being obtained by applying a composition in which a photoinitiator I-379EG (made by Ciba Japan K.K.) is dissolved in a proportion of 3% by mass to an A compound in the A compound on a polyethylene terephthalate (PET) film so that the coating film thickness becomes 30 μm, laminating a release-treated PET film on the obtained coating film, and exposing the laminate to 1,000 mJ/cm² using a high-precision exposure machine (“EXM-1172-B-∞” (trade name), made by ORC Manufacturing Co., Ltd.).

The adhesive composition according to the present invention more preferably contains an (A) component which becomes a polymer having a weight-average molecular weight of 100,000 to 1,000,000 (“high-molecular weight polymer”) when being irradiated with light, and an (A) component which becomes a polymer having a weight-average molecular weight of 1,000 to 50,000 (“low-molecular weight polymer”) when being irradiated with light. That a film-like adhesive formed contains both the “high-molecular weight polymer” and the “low-molecular weight polymer” can simultaneously satisfy highly all of the high-temperature adhesivity, the film handleability such as bleeding in roll processing, and the pressure-sensitive adhesivity and the hot fluidity in laminating.

The weight-average molecular weight of a polymer of an (A) component can be regulated by the exposure conditions (oxygen concentration, temperature, intensity), the amount of a photoinitiator, the addition of a thiol-, phenolic hydroxyl group-, amine- or phenol-based polymerization inhibitor, the kind of an acrylate, the blend amount of a thermosetting resin, and the viscosity of an adhesive composition.

(B) a photoinitiator is preferably one (B1 compound) having a molecular extinction coefficient for light of a wavelength of 365 nm of 100 ml/g·cm or higher, and more preferably one having that of 200 ml/g·cm or higher, from the viewpoint of improving the sensitivity. The time necessary for film making is preferably 60 sec or less, and from the viewpoint of being capable of manufacturing a film-like adhesive more efficiently, more preferably 30 sec or less. The molecular extinction coefficient can be determined by preparing a 0.001-mass % acetonitrile solution of a sample, and measuring an extinction of the solution using a spectrophotometer (“U-3310” (trade name), made by Hitachi High-Technologies Corp.).

The B1 compound is preferably an intermolecular cleavage-type photoinitiator from the viewpoint of the efficiency of film making, and examples thereof include aromatic ketones such as 2,2-dimethoxy-1,2-diphenylethan-1-one, 2-hydroxy-1-{4-[4-(2-hydroxy-2-methylpropionyl)-benzyl]-phenyl}-2-methyl-propan-1-one, 2-dimethylamino-2-(4-methyl-benzyl)-1-(4-morpholin-4-yl-phenyl)-but an-1-one, 2-benzyl-2-dimethylamino-1-(4-morpholinophenyl)-butanone-1,2-meth yl-1-(4-(methylthio)phenyl)-2-morpholinopropanone-1,1-[4-(phenylthio)-,2-(o-benzoyloxime)], ethanone,1-[9-ethyl-6-(2-methylbenzoyl)-9H-carbazol-3-yl]-,1-(o-acetyl oxime), 2,4-diethylthioxanthone, 2-ethylanthraquinone and phenanthrenequinone, benzyl derivatives such as benzyl dimethyl ketal, hexaarylbisimidazole derivatives such as 2,4,5-triarylimidazole dimmers such as a 2-(o-methoxyphenyl)-4,5-diphenylimidazole dimer, a 2-(p-methoxyphenyl)-4,5-diphenylimidazole dimer, a 2,4-di(p-methoxyphenyl)-5-phenylimidazole dimmer and a 2-(2,4-dimethoxyphenyl)-4,5-diphenylimidazole dimer, acridine derivatives such as 9-phenylacridine and 1,7-bis(9,9′-acridinyl)heptane, bisacylphosphine oxides such as bis(2,4,6,-trimethylbenzoyl)-phenylphosphine oxide, and compounds having maleimide. These can be used singly or in combinations of two or more.

Among the photoinitiators described above, 2,2-dimethoxy-1,2-diphenylethan-1-one, 2-benzyl-2-dimethylamino-1-(4-morpholinophenyl)-butanone-1, 2,2-dimethoxy-1,2-diphenylethan-1-one, 2-methyl-1-(4-(methylthio)phenyl)-2-morpholinopropan-1-one, 1-[4-(phenylthio)-,2-(o-benzoyloxime)], ethanone, 1-[9-ethyl-6-(2-methylbenzoyl)-9H-carbazol-3-yl]-, 1-(o-acetyl oxime) are preferably used from the viewpoint of the solubility of an adhesive composition containing no solvent.

The B1 compound is preferably a compound having an oxime ester skeleton or a morpholine skeleton in the molecule from the viewpoint of being capable of being efficiently made into a film by exposure even under an air atmosphere (in the presence of oxygen). Such a compound is not especially limited, but is preferably a compound having an oxime ester group represented by the following formula (B-1) and/or a compound having a morpholine ring represented by the following formula (B-2), (B-3) or (B-4). Specifically, 2-benzyl-2-dimethylamino-1-(4-morpholinophenyl)-butanone-1, 2,2-dimethoxy-1,2-diphenylethan-1-one, 2-methyl-1-(4-(methylthio)phenyl)-2-morpholinopropan-1-one, 1-[4-(phenylthio)-,2-(o-benzoyloxime)], ethanone,1-[9-ethyl-6-(2-methylbenzoyl)-9H-carbazol-3-yl]-,1-(o-acetyl oxime) are preferably used. Above all, 2-dimethylamino-2-(4-methyl-benzyl)-1-(4-morpholin-4-yl-phenyl)-but an-1-one is most preferably used from the viewpoint of being capable of highly satisfying the solubility to other components, the efficiency of film making (influences by the exposure amount and the atmosphere), the low sublimation, the preservation stability, the close contact after film making, and the adhesivity after curing.

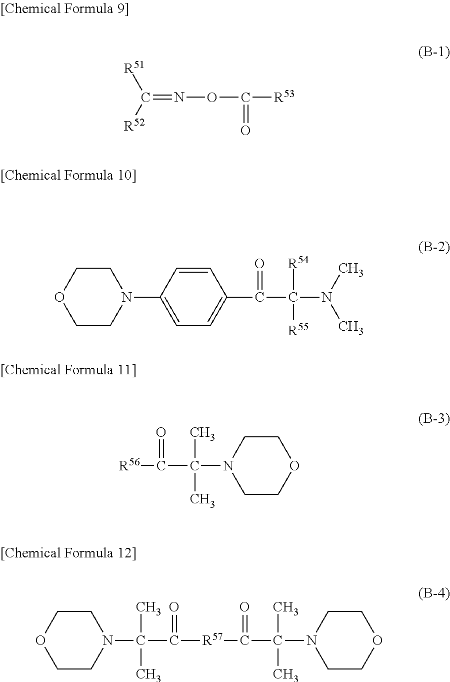

wherein R⁵¹ and R⁵² each independently denote a hydrogen atom, an alkyl group having 1 to 7 carbon atoms or an organic group containing an aromatic hydrocarbon group; R⁵³ denotes an alkyl group having 1 to 7 carbon atoms or an organic group containing an aromatic hydrocarbon group; R⁵⁴ and R⁵⁵ each denote a monovalent organic group; and R⁵⁶ and R⁵⁷ denote an organic group containing an aromatic hydrocarbon group.

The aromatic hydrocarbon group is not especially limited, but examples thereof include a phenyl group, a naphthyl group, benzoin derivatives, carbazole derivatives, thioxanthone derivatives and benzophenone derivatives. The aromatic hydrocarbon group may have a substituent.

The B1 compound is especially preferably a compound having an oxime ester group and/or a morpholine ring, and having a molecular extinction coefficient for light of a wavelength of 365 nm of 1,000 ml/g·cm or higher, and a 5%-weight loss temperature of 150° C. or higher.

Examples of such a B1 compound include compounds represented by the following formulae (B-5) to (B-9).

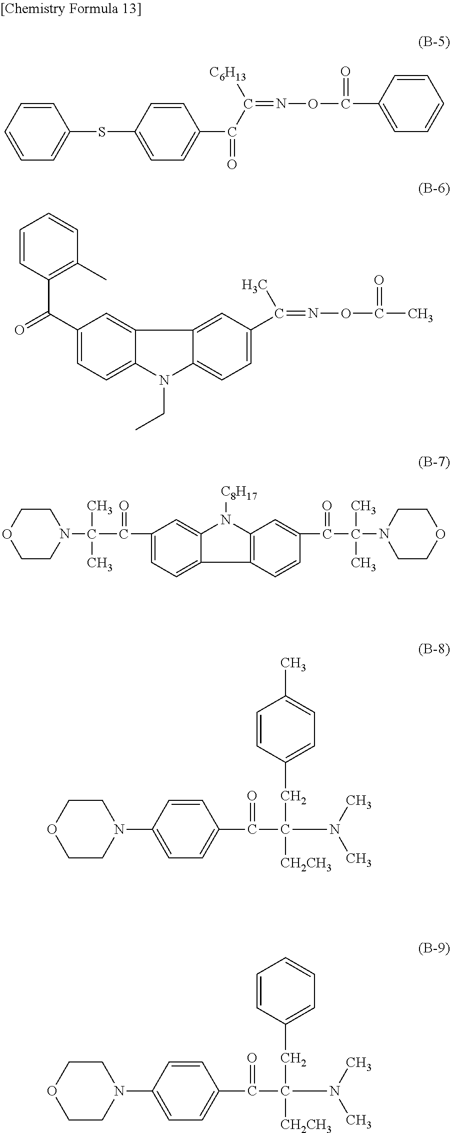

In a case where the adhesive composition according to the present invention contains an epoxy resin, the (B) component may contain a photoinitiator which develops a function to promote the polymerization and/or the reaction of the epoxy resin by radiation irradiation. Examples of such a photoinitiator include photobase generators to generate a base by radiation irradiation, and photoacid generators to generate an acid by radiation irradiation, and a photobase generator is especially preferable.

Use of a photobase generator can further improve the high-temperature adhesivity of an adhesive composition to an adherend and the moisture resistance thereof. The reason is conceivably because a base formed from a photobase generator efficiently acts as a curing catalyst of an epoxy resin, so that the crosslinking density can be enhanced more, and because the formed curing catalyst scarcely corrodes substrates and the like. Further, incorporation of a photobase generator in an adhesive composition can improve the crosslinking density, and can more decrease the outgas when the adhesive composition is left to stand at a high temperature. Additionally, the curing process can be decreased in the process temperature and the process time.

The photobase generator suffices if being a compound to generate a base on radiation irradiation. A base generated is preferably a strong basic compound from the viewpoint of the reactivity and the curing rate.

Examples of the base generated on radiation irradiation include imidazole derivatives such as imidazole, 2,4-dimethylimidazole and 1-methylimidazole, piperazine derivatives such as piperazine and 2,5-dimethylpiperazine, piperidine derivatives such as piperidine and 1,2-dimethylpiperidine, proline derivatives, trialkylamine derivatives such as trimethylamine, triethylamine and triethanolamine, pyridine derivatives whose 4-position is replaced by an amino group or an alklylamino group, such as 4-methylaminopyridine and 4-dimethylaminopyridine, pyrrolidine derivatives such as pyrrolidine and n-methylpyrrolidine, dihydropyridine derivatives, alicyclic amine derivatives such as triethylenediamine and 1,8-diazabiscyclo[5.4.0]undecene-1 (DBU), and benzylamine derivatives such as benzylmethylamine, benzyldimethylamine and benzyldiethylamine.

As a photobase generator to generate a base as described above on radiation irradiation, for example, quaternary ammonium salt derivatives can be used which are described in Journal of Photopolymer Science and Technology, Vol. 12, pp. 313-314 (1999), Chemistry of Materials, Vol. 11, pp. 170-176 (1999), and the like. Since these form a highly basic trialkylamine on irradiation of active light rays, these are best for curing epoxy resins.

As a photobase generator, carbamic acid derivatives can also be used which are described in Journal of American Chemical Society, Vol. 118, p. 12,925 (1996), Polymer Journal, Vol. 28, p. 795 (1996), and the like.

As a photobase generator to generate a base on radiation irradiation, oxime derivatives such as 2,4-dimethoxy-1,2-diphenylethan-1-one, 1,2-octanedione, 1-[4-(phenylthio)-,2-(O-benzoyloxime)] and ethanone,1-[9-ethyl-6-(2-methylbenzoyl)-9H-carbazol-3-yl]-, 1-(O-acety loxime), and 2-benzyl-2-dimethylamino-1-(4-morpholinophenyl)-butanone-1, 2,2-dimethoxy-1,2-diphenylethan-1-one, 2-methyl-1-(4-(methylthio)phenyl)-2-morpholinopropan-1-one and 2-benzyl-2-dimethylamino-1-(4-morpholinophenyl)-butanone-1, which are commercially available as photoradical generators, hexaarylbisimidazole derivatives (a substituent such as a halogen, an alkoxy group, a nitro group and a cyano group may be replaced by a phenyl group), benzisooxazolone derivatives, and the like can be used.

As a photobase generator, a compound may be used in which groups to generate a base are incorporated on the main chain and/or side chains of the polymer. The molecular weight in this case is preferably a weight-average molecular weight of 1,000 to 100,000, and more preferably 5,000 to 30,000, from the viewpoint of the adhesivity, the fluidity and the heat resistance as an adhesive.

Since the photobase generator exhibits no reactivity with an epoxy resin in the state of not being exposed, the photobase generator is very excellent in the storage stability at room temperature.

The content of (B) a photoinitiator is preferably 0.1 to 20 parts by mass, and from the viewpoint of the takt time in film making and the tackness after film making, more preferably 0.5 to 10 parts by mass, with respect to 100 parts by mass of an (A) component. If the content exceeds 20 parts by mass, the outgas becomes much, and the adhesivity and the preservation stability are likely to decrease. By contrast, if the content is less than 0.1 part by mass, film making is likely to be difficult.

The proportion of a B1 compound in (B) a photoinitiator is preferably 20 to 100 parts by mass, and more preferably 50 to 100 parts by mass, with respect to 100 parts by mass of the (B) component.

In the adhesive composition according to the present invention, a sensitizer, as required, can be concurrently used. Examples of the sensitizer include camphor quinone, benzil, diacetyl, benzyl dimethyl ketal, benzyl diethyl ketal, benzyl (2-methoxyethyl) ketal, 4,4′-dimethylbenzyl-dimethyl ketal, anthraquinone, 1-chloroanthraquinone, 2-chloroanthraquinone, 1,2-benzanthraquinone, 1-hydroxyanthraquinone, 1-methylanthraquinone, 2-ethylanthraquinone, 1-bromoanthraquinone, thioxanthone, 2-isopropylthioxanthone, 2-nitrothioxanthone, 2-methylthioxanthone, 2,4-dimethylthioxanthone, 2,4-diethylthioxanthone, 2,4-diisopropylthioxanthone, 2-chloro-7-trifluoromethylthioxanthone, thioxanthone-10,10-dioxide, thioxanthone-10-oxide, benzoin methyl ether, benzoin ethyl ether, isopropyl ether, benzoin isobutyl ether, benzophenone, bis(4-dimethylaminophenyl) ketone, 4,4′-bisdiethylaminobenzophenone and compounds containing an azido group. These can be used singly or concurrently in two or more.

The (C) thermosetting resin is not especially limited as long as the resin is a component composed of a reactive compound causing a crosslinking reaction by heat, and examples thereof include epoxy resins, cyanate ester resins, maleimide resins, allylnadiimide resins, phenol resins, urea resins, melamine resins, alkyd resins, acrylate resins, unsaturated polyester resins, diallyl phthalate resins, silicone resins, resorcinol formaldehyde resins, xylene resins, furan resins, polyurethane resins, ketone resins, triallyl cyanurate resins, polyisocyanate resins, resins containing tris(2-hydroxyethyl)isoyanurate, resins containing triallyl trimellitate, thermosetting resins synthesized from cyclopentadiene, and thermosetting resins obtained by trimerizing an aromatic dicyanamide. Above all, epoxy resins, maleimide resins and allylnadiimide resins are preferable from the viewpoint of being capable of developing an excellent adhesive force at high temperatures. The thermosetting resins can be used singly or in combinations of two or more.

The epoxy resin is preferably one having two or more epoxy groups in the molecule, and more preferably a glycidyl ether-type epoxy resin of phenol from the viewpoint of the thermocompression bondability, the curability and the physical properties of cured products. Examples of such a resin include bisphenol A (or AD, S, F) glycidyl ethers, hydrogenated bisphenol A glycidyl ethers, glycidyl ethers of ethylene oxide adducts of bisphenol A, glycidyl ethers of propylene oxide adducts of bisphenol A, glycidyl ethers of phenol novolac resins, glycidyl ethers of cresol novolac resins, glycidyl ethers of bisphenol A novolac resins, glycidyl ethers of naphthalene resins, trifunctional (or tetrafunctional) glycidyl ethers, glycidyl ethers of dicyclopentadiene phenol resins, glycidyl esters of dimer acids, trifunctional (or tetrafunctional) glycidylamines, and glycidylamines of naphthalene resins. These can be used singly or in combinations of two or more.

With respect to an epoxy resin, use of the epoxy resin which is a high-purity one in which alkaline metal ions, alkaline earth metal ions and halogen ions, especially chlorine ions, hydrolyzable chlorine and the like, as impurity ions, are decreased to 300 ppm or less, from the viewpoint of prevention of electromigration and corrosion-proofing of metal conductor circuits.

Examples of the maleimide resin include bismaleimide resins represented by the following formula (I), and novolac maleimide resins represented by the following formula (II).

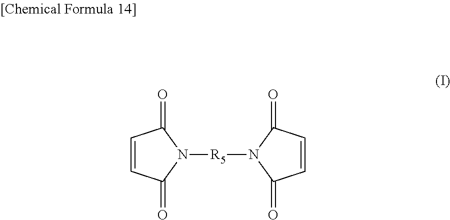

wherein R₅ denotes a divalent organic group containing an aromatic ring and/or a straight-chain, branched-chain or alicyclic hydrocarbon.

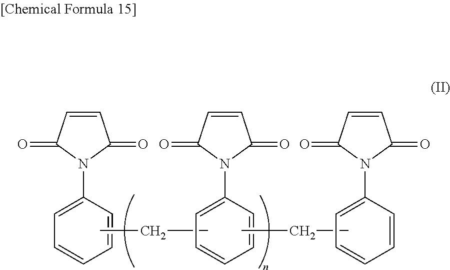

wherein n denotes an integer of 0 to 20.

Above all, from the viewpoint of being capable of imparting the heat resistance after curing and the high-temperature adhesive force of an adhesive film, bismaleimide resins represented by the following structural formula (III) and/or novolac maleimide resins represented by the above formula (II) are preferably used.

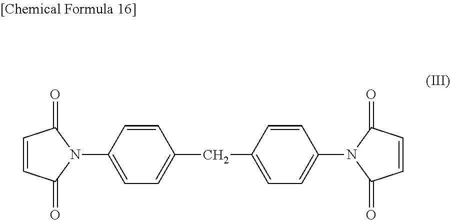

In order to cure the maleimide resin, an allylated bisphenol A, a cyanate ester compound or the like may be used concurrently, or a catalyst such as a peroxide may be added. The addition amount and the presence/absence of the addition of the compound or the catalyst described above are adjusted suitably in the range of securing target physical properties.

As the allylnadiimide resin, a compound containing two or more allylnadiimide groups in the molecule can be used, and examples thereof include bisallylnadiimide resins represented by the following formula (IV).

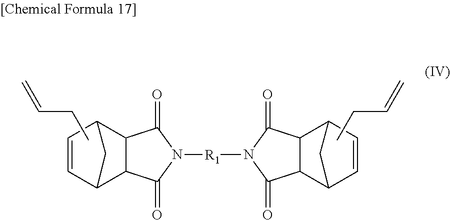

wherein R₁ denotes a divalent organic group containing an aromatic ring and/or a straight-chain, branched-chain or alicyclic hydrocarbon.

Above all, a liquid hexamethylene-type bisallylnadiimide represented by the following structural formula (V) and a solid xylylene-type bisallylnadiimide represented by the following structural formula (VI) and having a low melting point (melting point: 40° C.) are preferable from the viewpoint of being capable of imparting good hot fluidity. The solid xylylene-type bisallylnadiimide is more preferable from the viewpoint, in addition to the good hot fluidity, of being capable of suppressing a rise in the pressure-sensitive adhesivity after being rendered into a B-stage, and of the handleability and the easy delamination from a dicing tape in pickup, and being capable of suppressing refusion of cut surfaces after dicing.

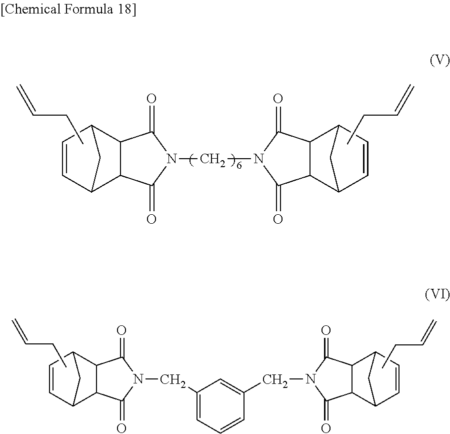

The bisallylnadiimide can be used singly or in combinations of two or more.

The allylnadiimide resin needs a curing temperature of 250° C. or higher for non-catalyst single curing, which presents an obstacle for practical use; and also in a system using a catalyst, only a catalyst having metal corrosiveness causing serious defects on electronic materials, such as a strong acid or an onium salt, can be used, and a temperature of about 250° C. is needed for final curing, but concurrent use of the allylnadiimide resin and one of a di- or more polyfunctional acrylate or methacrylate compound, or a maleimide resin allows curing at a low temperature of 200° C. or lower (literature: A. Renner, A. Kramer, “Allylnadic-Imides: A New Class of Heat-Resistant Thermosets”, J. Polym. Sci., Part A Polym. Chem., 27, 1301 (1989)).

With respect to (C) a thermosetting resin, any one can be used irrespective of being liquid or solid at room temperature. In the case of a liquid thermosetting resin, a lower viscosity can be made; and in the case of a solid thermosetting resin, the tackness after light irradiation can be reduced more. A liquid thermosetting resin and a solid thermosetting resin may be concurrently used.

In the case of using a liquid thermosetting resin, the viscosity is preferably 10,000 mPa·s or lower, more preferably 5,000 mPa·s or lower, still more preferably 3,000 mps or lower, and most preferably 2,000 mPa·s or lower. If the viscosity exceeds 10,000 mPa·s, the viscosity of an adhesive composition rises, and thin film making is likely to become difficult. Such a liquid thermosetting resin is not especially limited, but is preferably an epoxy resin from the viewpoint of the adhesivity and the heat resistance; and especially trifunctional (or tetrafunctional) glycidylamines and bisphenol A (or AD, S, F) glycidyl ethers are preferably used.

In the case of using a solid thermosetting resin, the resin can be used, for example, by being dissolved in an (A) component. The solid thermosetting resin is not especially limited, but has a molecular weight of 2,000 or lower and preferably 1,000 or lower, and has a softening point of 100° C. or lower and preferably 80° C. or lower, from the viewpoint of the thermocompression bondability and the viscosity. Tri- or more polyfunctional epoxy resins are preferable from the viewpoint of the adhesivity and the heat resistance. As such an epoxy resin, for example, an epoxy resin having the following structure is preferably used.

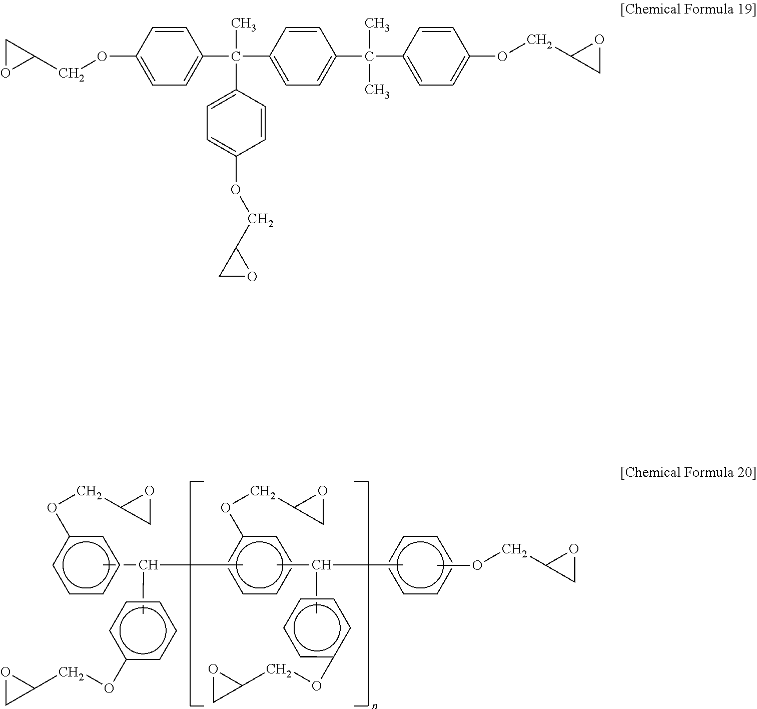

wherein n denotes an integer of 0 to 10.

As (C) the thermosetting resin, a thermosetting resin having a 5%-weight loss temperature of 150° C. or higher is preferable; one having 180° C. or higher is more preferable; and one having 200° C. or higher is still more preferable. Here, the 5%-weight loss temperature of a thermosetting resin refers to a 5%-weight loss temperature when the thermosetting resin is measured using a simultaneous thermogravimetric/differential thermal analyzer (TG/DTA6300, made by SII Nano Technology Inc.) at temperature-rise rate of 10° C./min in a nitrogen flow (400 ml/min). Application of a thermosetting resin having a high 5%-weight loss temperature can suppress the vaporization in thermocompression bonding or thermosetting. The thermosetting resin having such a heat resistance includes an epoxy resin having an aromatic group in the molecule; and especially trifunctional (or tetrafunctional) glycidylamines and bisphenol A (or AD, S, F) glycidyl ethers are preferably used from the viewpoint of the adhesivity and the heat resistance.

The content of (C) a thermosetting resin is preferably 1 to 100 parts by mass, and more preferably 2 to 50 parts by mass, with respect to 100 parts by mass of an (A) component. If the content exceeds 100 parts by mass, the tackness after exposure is likely to rise. By contrast, if the content is less than 2 parts by mass, it is likely that a sufficient high-temperature adhesivity cannot be obtained.

In the adhesive composition according to the present invention, it is preferable that a curing accelerator is further contained. The curing accelerator is not especially limited as long as being a compound to promote curing/polymerization of an epoxy resin by heating, and examples thereof include phenolic compounds, aliphatic amines, alicyclic amines, aromatic polyamines, polyamides, aliphatic acid anhydrides, alicyclic acid anhydrides, aromatic acid anhydrides, dicyandiamide, organic acid dihydrazides, boron trifluoride amine complexes, imidazoles, dicyandiamide derivatives, dicarboxylic acid dihydrazides, triphenylphosphine, tetraphenylphosphonium tetraphenylborate, 2-ethyl-4-methylimidazole-tetraphenylborate, 1,8-diazabicyclo[5.4.0]undecene-7-tetraphenylborate and tertiary amines. Above all, imidazoles are preferably used from the viewpoint of the solubility and the dispersibility when no solution is contained. The content of a curing accelerator is preferably 0.01 to 50 parts by mass with respect to 100 parts by mass of an epoxy resin. Additionally, imidazoles are especially preferable also from the viewpoint of the adhesivity, the heat resistance and the preservation stability.

The imidazoles preferably have a reaction initiation temperature of 50° C. or higher, and more preferably 80° C. or higher. If the reaction initiation temperature is 50° C. or lower, since the preservation stability decreases, the viscosity of a resin composition rises and the control of the film thickness becomes difficult, which is not preferable.

As the imidazoles, an imidazole which dissolves in an epoxy resin is preferably used. Use of such an imidazole can provide a coating film having few irregularities. Such imidazoles are not especially limited, but include 2-undecylimidazole, 2-heptadecylimidazole, 1,2-dimethylimidazole, 2-ethyl-4-methylimidazole, 1-benzyl-2-methylimidazole, 1-benzyl-2-phenylimidazole, 1-cyanoethyl-2-methylimidazole, 1-cyanoethyl-2-ethyl-4-methylimidazole and 1-cyanoethyl-2-phenylimidazole.

As the imidazoles, compounds can be used which are pulverized into an average particle diameter of preferably 10 μm or smaller, more preferably 8 μm or smaller, and most preferably 5 μm or smaller. Use of imidazoles having such a particle diameter can suppress the viscosity change of an adhesive composition, and can also suppress sedimentation of the imidazoles. When a thin film is formed, irregularities on the surface can be reduced; thereby, a uniform film can be obtained. Further since curing in a resin in the curing time can be made to progress homogeneously, the outgas can be decreased.

The adhesive composition according to the present invention can further contain (D) a curing agent. Examples of the curing agent include phenolic compounds. As the phenolic compound, a compound is more preferable which has two or more phenolic hydroxyl groups in the molecule. Examples of such a compound include phenol novolacs, cresol novolacs, t-butylphenol novolacs, dicyclopentadiene cresol novolacs, dicyclopentadiene phenol novolacs, xylylene-modified phenol novolacs, naphtholic compounds, trisphenolic compounds, tetrakisphenol novolacs, bisphenol A novolacs, poly-p-vinylphenols, phenol aralkyl resins and allyl-modified phenol novolacs. Above all, compounds having a number-average molecular weight in the range of 400 to 4,000 are preferable, and those being liquid at room temperature are more preferable. Thereby, the outgas in heating causing contaminations to semiconductor elements or devices in assembling and heating of semiconductor devices can be suppressed. The phenolic compounds are preferably liquid, and since allyl-modified phenol novolacs are liquid and highly heat-resistive, these can suitably be used.

The content of a phenolic compound is preferably 50 to 120 parts by mass, and more preferably 70 to 100 parts by mass, with respect to 100 parts by mass of a thermosetting resin.

The adhesive composition according to the present invention can further contain (E) a thermoradical generator. The thermoradical generator is preferably an organic peroxide. The organic peroxide preferably has a one-minute half-life temperature of 80° C. or higher, more preferably 100° C. or higher, and most preferably 120° C. or higher. An organic peroxide is selected in consideration of the preparation condition of an adhesive composition, the film making temperature, the curing (lamination) condition, other process conditions, the storage stability and the like. A peroxide usable is not especially limited, but examples thereof include 2,5-dimethyl-2,5-di(t-butylperoxyhexane), dicumylperoxide, t-butylperoxy-2-ethylhexanate, t-hexylperoxy-2-ethylhexanate, 1,1-bis(t-butylperoxy)-3,3,5-trimethylcyclohexane, 1,1-bis(t-hexylperoxy)-3,3,5-trimethylcyclohexane and bis(4-t-butylcyclohexyl)peroxydicarbonate, and these can be used singly or in combinations of two or more. Incorporation of the organic peroxide allows reacting the unreacted radiation-polymerizable compound remaining after exposure, and allows achieving low outgas and high adhesion.

Examples of a thermoradical generator having a one-minute half-life temperature of 80° C. or higher include Perhexa 25B (made by NOF Corp.), 2,5-dimethyl-2,5-di(t-butylperoxyhexane)(one-minute half-life temperature: 180° C.), and Percumyl D (made by NOF Corp.), dicumylperoxide (one-minute half-life temperature: 175° C.).

The content of (E) a thermoradical generator is preferably 0.01 to 20% by mass, more preferably 0.1 to 10% by mass, and most preferably 0.5 to 5% by mass, with respect to the total amount of (A) a radiation-polymerizable compound. If the content of a thermoradical generator is less than 0.01% by mass, the curability decreases and the addition effect becomes small; and if that exceeds 5% by mass, an increase in the outgas and a decrease in the preservation stability are observed.

The adhesive composition according to the present invention may further contain (F) a thermoplastic resin from the viewpoint of improving the low stress, the close contact and the thermocompression bondability with an adherend.

Tg of an (F) component is preferably 150° C. or lower, more preferably 120° C. or lower, still more preferably 100° C. or lower, and most preferably 80° C. or lower. If the Tg exceeds 150° C., the viscosity of an adhesive composition is likely to increase. Additionally, a high temperature of 150° C. or higher is needed when the adhesive composition is thermocompression bonded to an adherend, and warping of semiconductor wafers is likely to occur.

Here, “Tg” of an (F) component refers to a primary dispersion peak temperature when the (F) component is made into a film. Specifically, a film of an (F) component is measured using a viscoelasticity analyzer “RSA-2” (trade name), made by Rheometrics Scientific Inc., under the conditions of a film thickness of 100 a temperature-rise rate of 5° C./min, a frequency of 1 Hz and a measurement temperature range of −150° C. to 300° C., and a tan δ peak temperature near Tg is determined as Tg.

The weight-average molecular weight of an (F) component is preferably controlled in the range of 5,000 to 500,000. More preferably, the weight-average molecular weight of the (F) component is 10,000 to 300,000 from the viewpoint of simultaneously satisfying highly both the thermocompression bondability and the high-temperature adhesivity. Here, the “weight-average molecular weight” refers to a weight-average molecular weight when using a high-performance liquid chromatography “C-R4A” (trade name), made by Shimadzu Corp., the measurement is carried out in terms of polystyrene.

Examples of the (F) component include polyester resins, polyether resins, polyimide resins, polyamide resins, polyamidoimide resins, polyetherimide resins, polyurethane resins, polyurethaneimide resins, polyurethaneamidoimide resins, siloxane polyimide resins, polyesterimide resins, copolymers thereof, precursors (polyamic acid and the like), and additionally polybenzoxazol resins, phenoxy resins, polysulfone resins, polyether sulfone resins, polyphenylene sulfide resins, polyester resins, polyether resins, polycarbonate resins, polyether ketone resins, (meth)acryl copolymers having a weight-average molecular weight of 10,000 to 1,000,000, novolac resins and phenol resins. These can be used singly or in combinations of two or more. These resins may be ones whose main chain and/or side chains are imparted with a glycol group of ethylene glycol, propylene glycol or the like, a carboxyl group and/or a hydroxyl group.

Above all, the (F) component is preferably a resin having an imido group from the viewpoint of the high-temperature adhesivity and the heat resistance. Examples of a resin having an imido group include polyimide resins, polyamidoimide resins, polyetherimide resins, polyurethaneimide resins, polyurethaneamidoimide resins, siloxane polyimide resins, polyesterimide resins, copolymers thereof and polymers of monomers having an imido group. Above all, the (F) component is preferably a polyimide resin and/or a polyamideimide resin.

A polyimide resin and/or a polyamideimide resin is obtained, for example, by condensation reacting a tetracarboxylic dianhydride and a diamine by a well-known method. That is, a tetracarboxylic dianhydride and a diamine are addition reacted in an organic solvent at a reaction temperature of 80° C. or lower, preferably 0° C. to 60° C., equimolarly or as required, by adjusting the compositional ratio (the adding order of each component is optional) in the range of preferably 0.5 to 2.0 mol, more preferably 0.8 to 1.0 mol, of the total of the diamine with respect to 1.0 mol of the total of the tetracarboxylic dianhydride. The viscosity of the reaction liquid gradually increases as the reaction progresses, and polyamic acid as a precursor of a polyimide resin is formed. In order to suppress decreases in various physical properties of a resin composition, the tetracarboxylic dianhydride is preferably one having being subjected to a recrystallization refining treatment with acetic anhydride.

With respect to the compositional ratio of a tetracarboxylic dianhydride and a diamine, if the total of the diamine exceeds 2.0 mol with respect to 1.0 mol of the total of the tetracarboxylic dianhydride, in a polyimide resin and/or a polyamideimide resin obtained, the amount of polyimide oligomers having amine terminals is likely to become much, and the weight-average molecular weights of the polyimide resin and/or the polyamideimide resin decrease, which is likely to give insufficient various physical properties including heat resistance of a resin composition. By contrast, if the total of the diamine is less than 0.5 mol with respect to 1.0 mol of the total of the tetracarboxylic dianhydride, the amount of polyimide oligomers having acid terminals is likely to become much, and the weight-average molecular weights of the polyimide resin and/or the polyamideimide resin decrease, which is likely to give insufficient various physical properties including heat resistance of the resin composition.

A polyimide resin and/or a polyamideimide resin can be obtained by cyclodehydrating the reaction product (polyamic acid). The cyclodehydration can be carried out by a thermal ring-closure method using a heating treatment, a chemical ring closure method using a dehydrating agent, or the like.

As a tetracarboxylic dianhydride used as a raw material of a polyimide resin and/or a polyamideimide resin, for example, from the viewpoint of being capable of decreasing the linear expansion coefficient, acid dianhydrides having a biphenyl skeleton such as 3,3′,4,4′-biphenyltetracarboxylic dianhydride, 2,2′,3,3′-biphenyltetracarboxylic dianhydride, 2,3,3′,4′-biphenyltetracarboxylic dianhydride and 3,4,3′,4′-biphenyltetracarboxylic dianhydride, and acid dianhydrides having a naphthyl skeleton such as 1,2,5,6-naphthalenetetracarboxylic dianhydride, 1,4,5,8-naphthalenetetracarboxylic dianhydride, 2,3,6,7-naphthalenetetracarboxylic dianhydride and 1,2,4,5-naphthalenetetracarboxylic dianhydride, are preferably used. From the viewpoint of being capable of improving the sensitivity of the formation of a B-stage, acid dianhydrides having a benzophenone skeleton such as 3,4,3′,4′-benzophenonetetracarboxylic dianhydride, 2,3,2′,3′-benzophenonetetracarboxylic dianhydride and 3,3,3′,4′-benzophenonetetracarboxylic dianhydride, are preferably used. Further from the viewpoint of the transparency, acid dianhydrides having an alicyclic skeleton such as 1,2,3,4-butanetetracarboxylic dianhydride, decahydronaphthalene-1,4,5,8-tetracarboxylic dianhydride, 4,8-dimethyl-1,2,3,5,6,7-hexahydronaphthalene-1,2,5,6-tetracarboxylic dianhydride, cyclopentane-1,2,3,4-tetracarboxylic dianhydride, 1,2,3,4-cyclobutanetetracarboxylic dianhydride, bis(exo-bicyclo [2.2.1]heptane-2,3-dicarboxylic dianhydride and bicyclo-[2.2.2]-oct-7-ene-2,3,5,6-tetracarboxylic dianhydride, and acid dianhydrides having a fluoroalkyl group such as 2,2-bis(3,4-dicarboxyphenyl)hexafluoropropane dianhydride, 2,2-bis[4-(3,4-dicarboxyphenyl)phenyl]hexafluoropropane dianhydride, 1,4-bis(2-hydroxyhexafluoroisopropyl)benzenebis(trimellitic anhydride) and 1,3-bis(2-hydroxyhexafluoroisopropyl)benzenebis(trimellitic anhydride), are preferably used.

Further from the viewpoint of the transparency to 365 nm, a tetracarboxylic dianhydride represented by the following formula (1), and the like are preferably used. In the following formula (1), a denotes an integer of 2 to 20.

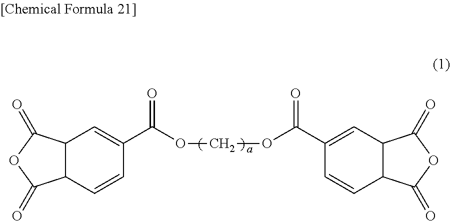

The tetracarboxylic dianhydride represented by the above formula (1) can be synthesized, for example, from anhydrous trimellitic monochloride and a diol corresponding thereto, and specifically includes 1,2-(ethylene)bis(trimellitate anhydride) 1,3-(trimethylene)bis(trimellitate anhydride), 1,4-(tetramethylene)bis(trimellitate anhydride), 1,5-(pentamethylene)bis(trimellitate anhydride), 1,6-(hexamethylene)bis(trimellitate anhydride), 1,7-(heptamethylene)bis(trimellitate anhydride), 1,8-(octamethylene)bis(trimellitate anhydride), 1,9-(nonamethylene)bis(trimellitate anhydride), 1,10-(decamethylene)bis(trimellitate anhydride), 1,12-(dodecamethylene)bis(trimellitate anhydride), 1,16-(hexadecamethylene)bis(trimellitate anhydride) and 1,18-(octadecamethylene)bis(trimellitate anhydride). These compounds can decrease Tg without spoiling the heat resistance.

Further as the tetracarboxylic dianhydride, a tetracarboxylic dianhydride represented by the following formula (2) or (3) is preferable from the viewpoint of imparting the good solubility to an (A) component, the transparency to light of 365 nm, and the thermocompression bondability.

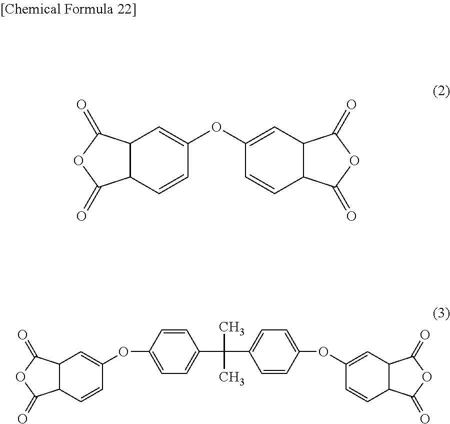

The tetracarboxylic dianhydrides as described above can be used singly or in combinations of two or more.

As the (F) component, a polyimide resin containing a carboxyl group and/or a phenolic hydroxyl group can further be used from the viewpoint of raising the adhesive strength. A diamine used as a raw material for the polyimide resin containing a carboxyl group and/or a hydroxyl group preferably contains an aromatic diamine represented by the following formula (4), (5), (6) or (7).

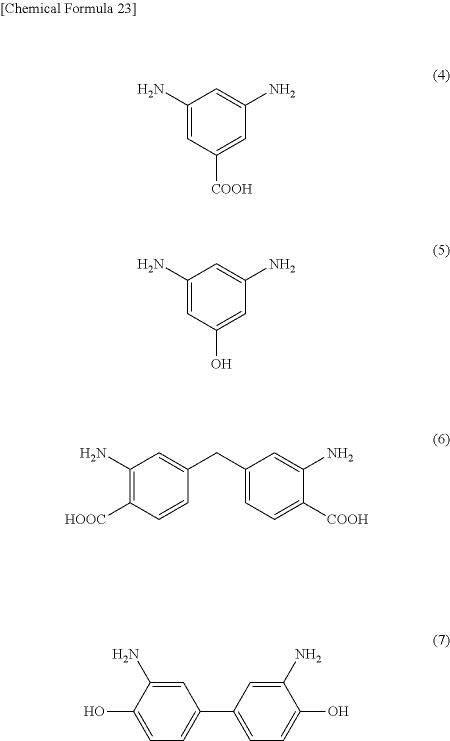

Other diamines used as a raw material for the polyimide resin and/or the polyamideimide resin are not especially limited, but the following diamines can be used to regulate Tg and the solubility of the polymer. For example, from the viewpoint of being capable of improving the heat resistance and the adhesivity, o-phenylenediamine, m-phenylenediamine, p-phenylenediamine, bis(4-amino-3,5-dimethylphenyl)methane, bis(4-amino-3,5-diisopropylphenyl)methane, 2,2-bis(3-aminophenyl)propane, 2,2′-(3,4′-diaminodiphenyl)propane, 2,2-bis(4-aminophenyl)propane, 1,3-bis(3-aminophenoxy)benzene, 1,4-bis(3-aminophenoxy)benzene, 1,4-bis(4-aminophenoxy)benzene, 3,3′-(1,4-phenylenebis(1-methylethylidene))bisaniline, 3,4′-(1,4-phenylenebis(1-methylethylidene))bisaniline, 4,4′-(1,4-phenylenebis(1-methylethylidene))bisaniline, 2,2-bis(4-(3-aminophenoxy)phenyl)propane and 2,2-bis(4-aminophenoxyphenyl)propane, are preferably used. From the viewpoint of being capable of decreasing the linear expansion coefficient, 3,3′-diaminodiphenyl ether, 3,4′-diaminodiphenyl ether, 4,4′-diaminodiphenyl ether, 3,3′-diaminodiphenylmethane, 3,4′-diaminodiphenylmethane, 4,4′-diaminodiphenylmethane, 3,3′-diaminodiphenyl sulfone, 3,4′-diaminodiphenyl sulfone, 4,4′-diaminodiphenyl sulfone, bis(4-(3-aminoenoxy)phenyl) sulfone, bis(4-(4-aminoenoxy)phenyl) sulfone and 3,3′-dihydroxy-4,4′-diaminobiphenyl, are preferably used. From the viewpoint of being capable of improving the close contact with an adherend such as a metal, 3,3′-diaminodiphenyl sulfide, 3,4′-diaminodiphenyl sulfide, 4,4′-diaminodiphenyl sulfide, bis(4-(3-aminoenoxy)phenyl) sulfide and bis(4-(4-aminoenoxy)phenyl) sulfide, are preferably used. Diamines capable of decreasing Tg include 1,3-bis(aminomethyl)cyclohexane, and an aliphatic etherdiamine represented by the following formula (8) and a siloxanediamine represented by the following formula (9).

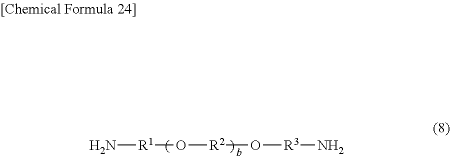

wherein R¹, R² and R³ each independently denote an alkylene group having 1 to 10 carbon atoms; and b denotes an integer of 2 to 80.

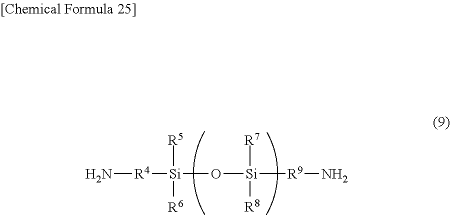

wherein R⁴ and R⁹ each independently denote an alkylene group having 1 to 5 carbon atoms or a phenylene group which may have a substituent; R⁵, R⁶, R⁷ and R⁸ each independently denote an alkyl group having 1 to 5 carbon atoms, a phenyl group or a phenoxy group; and d denotes an integer of 1 to 5.

Among the diamines described above, an aliphatic etherdiamine represented by the formula (8) is preferable, and an ethylene glycol-based and/or a propylene glycol-based diamine is more preferable, from the viewpoint of imparting compatibility with other components.

Such an aliphatic etherdiamine specifically includes aliphatic diamines such as polyoxyalkylenediamines such as Jeffamine D-230, D-400, D-2000, D-4000, ED-600, ED-900, ED-2000 and EDR-148, made by Sun Technochemical Co., Ltd., and polyetheramines D-230, D-400 and D-2000, made by BASF AG. These diamines are preferably contained in 20 mol % or more in the total diamines, and from the viewpoint of the compatibility with other blend components such as (A) a radiation-polymerizable compound and (C) a thermosetting resin, and of being capable of simultaneously satisfying highly both the thermocompression bondability and the high-temperature adhesivity, are more preferably in 50 mol % or more.

The diamine is preferably a siloxanediamine represented by the above formula (9) from the viewpoint of imparting the close contact and the adhesivity at room temperature.

These diamines are preferably contained in 0.5 to 80 mol % in the total diamines, and from the viewpoint of being capable of simultaneously satisfying highly both the thermocompression bondability and the high-temperature adhesivity, are more preferably in 1 to 50 mol %. If the content is less than 0.5 mol %, the effect of the addition of siloxanedimaines is likely to become small; and if the content exceeds 80 mol %, the compatibility with other components, and the high-temperature adhesivity are likely to decrease.

The above-mentioned diamines can be used singly or in combinations of two or more.

The polyimide resin and/or the polyamideimide resin can be used singly or as required, as a blend of two or more.

As described above, when a composition of a polyimide resin and/or a polyamideimide resin is determined, the composition is preferably so designed that the Tg becomes 150° C. or lower, and as the diamine as a raw material of a polyimide resin, an aliphatic etherdiamine represented by the above formula (8) is especially preferably used.

When the polyimide resin and/or the polyamideimide resin is synthesized, by charging a monofunctional acid anhydride like a compound represented by the following formula (10), (11) or (12) and/or a monofunctional amine in a condensation reaction liquid, functional groups excluding acid anhydrides and diamines can be incorporated to polymer terminals. Thereby, the molecular weight of the polymer can be decreased; the viscosity of an adhesive resin composition can be reduced; and the thermocompression bondability can be improved.

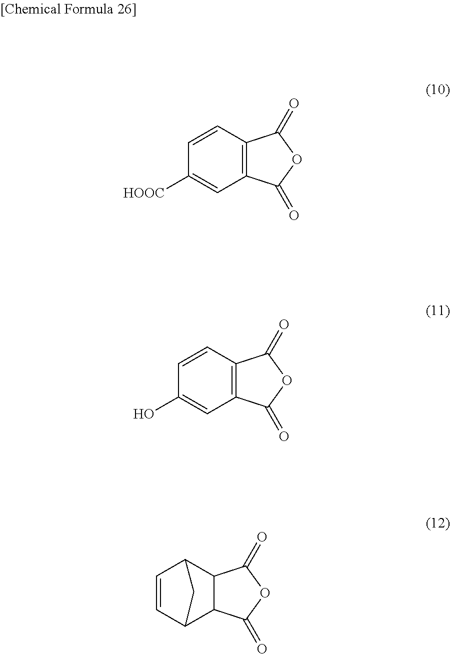

(F) a thermoplastic resin may have functional groups, such as imidazole, having a function to promote the curing of an epoxy resin on the main chain and/or side chains. A polyimide containing imidazole can be obtained, for example, by using a diamine containing an imidazole group represented by the following structural formula as a part of a diamine component shown in the above. Such a polymer having imidazole on the side chain is preferable because of being capable of improving the compatibility and the preservation stability.

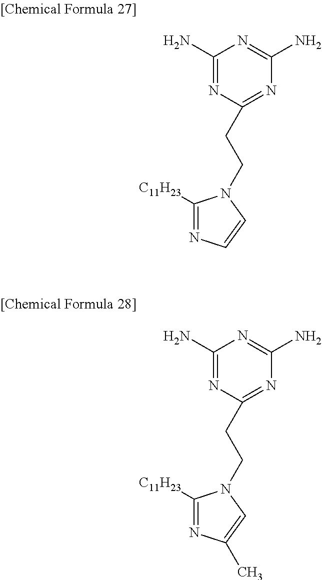

The polyimide resin and/or the polyamideimide resin preferably has a transmittance, at 365 nm when molded into 30 μm, of 10% or higher in order to be able to be uniformly rendered into a B-stage, and more preferably 20% or higher in order to be able to be rendered into a B-stage at a small exposure amount. Such a polyimide resin and/or a polyamideimide resin can be synthesized, for example, by reacting an acid anhydride represented by the above formula (2) with an aliphatic etherdiamine represented by the above formula (8) and/or a siloxanediamine represented by the above formula (9).

As (F) a thermoplastic resin, a liquid thermoplastic resin being liquid at normal temperature (25° C.) is preferably used from the viewpoint of suppressing a rise in the viscosity and further reducing the undissolved residues in an adhesive composition. Such a thermoplastic resin allows the reaction by heating without using any solvent, and is useful in an adhesive composition using no solvent as in the present invention, in the points of eliminating a step of removing a solvent, reducing a remaining solvent, and eliminating a step of reprecipitation. Additionally, a liquid thermoplastic resin is easy to take out from a reaction furnace. Examples of such a liquid thermoplastic resin include rubbery polymers such as polybutadiene, acrylonitrile-butadiene oligomers, polyisoprene and polybutene, polyolefin, acrylic polymers, silicone polymers, polyurethane, polyimide, polyamideimide. Above all, a polyimide resin and/or a polyamideimide resin is preferably used.

A liquid polyimide resin and/or polyamideimide resin can be obtained, for example, by reacting an acid anhydride described above with an aliphatic etherdiamine or a siloxanediamine. A synthesis method includes a method in which an acid anhydride is dispersed in an aliphatic etherdiamine or a siloxanediamine without adding any solution, and heated.

The content of (F) a thermoplastic resin is preferably 0.1 to 50% by mass, and from the viewpoint of the film formability, the uniformity of the film thickness and the suppression of a rise in the viscosity, is more preferably 0.5 to 20% by mass, with respect to an (A) component. If the content of a thermoplastic resin is less than 0.1% by mass, the effect of the addition is likely to disappear; and if the content exceeds 50% by mass, the uniformity of the film thickness is likely to decrease due to the undissolved residues, and film thickness reduction is likely to become difficult due to a rise in the viscosity.

To the adhesive composition according to the present invention, a polymerization inhibitor or an antioxidant may further be added, such as quinones, polyhydric phenols, phenols, phosphites and sulfurs, in the addition range of not spoiling the curability, in order to impart the preservation stability, the process adaptability or the antioxidant property.

The adhesive composition according to the present invention may further contain a filler suitably. Examples of the filler include metal fillers such as silver powder, gold powder, copper powder and nickel powder, inorganic fillers such as alumina, aluminum hydroxide, magnesium hydroxide, calcium carbonate, magnesium carbonate, calcium silicate, magnesium silicate, calcium oxide, magnesium oxide, aluminum oxide, aluminum nitride, crystalline silica, amorphous silica, boron nitride, titania, glass, iron oxide and ceramics, carbon, and organic fillers such as rubbery fillers, and these can be used without any especial limitation, not depending on the kind, the shape and the like.

The filler can be used properly according to desired functions. For example, metal fillers are added for the purpose of imparting the electroconductivity, the thermal conductivity, the thixotropy and the like to an adhesive composition; non-metal inorganic fillers are added for the purpose of imparting the thermal conductivity, the low thermal expansion, the low moisture absorption and the like to an adhesive layer; and organic fillers are added for the purpose of imparting the toughness and the like to an adhesive layer.

These metal fillers, inorganic fillers and organic fillers can be used singly or in combinations of two or more. Above all, metal fillers, inorganic fillers or insulative fillers are preferable from the viewpoint of being capable of imparting the electroconductivity, the thermal conductivity, the low moisture absorption, the insulation and the like, which are required for adhesive materials for semiconductor devices; and among inorganic fillers or insulative fillers, a silica filler is more preferable from the viewpoint of exhibiting good dispersibility to an adhesive composition and being capable of imparting a high adhesive force during a hot time.

The filler preferably has an average particle diameter of 10 μm or smaller and a maximum particle diameter of 30 μm or smaller, and more preferably an average particle diameter of 5 μm or smaller and a maximum particle diameter of 20 μm or smaller. If the average particle diameter exceeds 10 μm or the maximum particle diameter exceeds 30 μm, the effect of improving the fracture toughness is unlikely to be obtained sufficiently. The lower limits of the average particle diameter and the maximum particle diameter are not especially limited, but either is preferably 0.001 μm or larger.

The content of the filler is determined according to imparted properties and functions, but is preferably 50% by mass or less, more preferably 1 to 40% by mass, and still more preferably 3 to 30% by mass, with respect to the total amount of an adhesive composition containing the filler. By increasing the amount of the filler, low alpha-particle emission, low moisture absorption and high elastic modulus can be achieved, and the dicing property (cutting property with a dicer blade), wire bondability (ultrasonic efficiency) and adhesive strength during a hot time can be improved effectively. If a filler is added in more than necessary, the viscosity rises and the thermocompression bondability is likely to be spoiled; therefore, the content of the filler preferably falls in the range described above. An optimum filler content can be determined to balance required properties. Mixing and kneading in the case of using a filler can be carried out using a suitable combination of common dispersing machines such as a stirrer, a grinder, a three-roll mill and a ball mill.

The adhesive composition according to the present invention may contain various types of coupling agents in order to make good the interfacial bond between dissimilar materials. Examples of the coupling agent include silane-, titanium- and aluminum-based ones; above all, silane-based coupling agents are preferable from the viewpoint of a high effect; and compounds having a thermosetting group such as an epoxy group, and a radiation-polymerizable group such as a methacrylate and/or an acrylate are more preferable.

The boiling point and/or the decomposition temperature of the silane-based coupling agent is preferably 150° C. or higher, more preferably 180° C. or higher, and still more preferably 200° C. or higher. A silane-based coupling agent is most preferably used which has a boiling point and/or a decomposition temperature of 200° C. or higher, and has a thermosetting group such as an epoxy group and a radiation-polymerizable group such as a methacrylate and/or an acrylate.

The use amount of a coupling agent is preferably 0.01 to 20 parts by mass with respect to 100 parts by mass of an adhesive composition from the viewpoint of the effect and the heat resistance and the cost.

The adhesive composition according to the present invention may further contain an ion scavenger in order to adsorb ionic impurities and make good the insulation reliability in moisture absorption. Such an ion scavenger is not especially limited, and examples thereof include compounds known as copper inhibitors for preventing copper from eluting as ions, such as a triazinethiol compounds and phenolic reducing agents, and powdery inorganic compounds such as bismuth-, antimony-, magnesium-, aluminum-, zirconium-, calcium-, titanium- and tin-based ones and mixtures thereof. Specific examples are inorganic ion scavengers made by Toagosei Co., Ltd., trade names, IXE-300 (antimony-based), IXE-500 (bismuth-based), IXE-600 (antimony-bismuth mixture-based), IXE-700 (magnesium-aluminum mixture-based), IXE-800 (zirconium-based) and IXE-1100 (calcium-based). These can be used singly or as a mixture of two or more. The use amount of the ion scavenger is preferably 0.01 to 10 parts by mass with respect to 100 parts by mass of an adhesive composition from the viewpoint of the effect of the addition, the heat resistance, the cost and the like.

The adhesive composition according to the present invention preferably contains a compound having an imide group. The compound having an imide group can contain, for example, a low-molecular compound such as a monofunctional (meth)acrylate having an imide group cited as the A1 compound, and a resin having an imide group such as a polyimide resin cited as the (F) component.

The adhesive composition according to the present invention preferably has a viscosity at 25° C. of 10 to 30,000 mPa·s, more preferably 30 to 20,000 mPa·s, still more preferably 50 to 10,000 mPa·s, and most preferably 100 to 5,000 mPa·s. If the viscosity is lower than 10 mPa·s, the preservation stability and the heat resistance of an adhesive composition are likely to decrease, and pinholes are likely to occur when the adhesive composition is applied. Further, film making by exposure is likely to become difficult. If the viscosity exceeds 30,000 mPa·s, the film-thickness reduction in application is likely to become difficult, and the discharge from a nozzle is likely to become difficult.

In the adhesive composition according to the present invention, the adhesive composition made into a film by light irradiation preferably has a 5%-weight loss temperature of 150° C. or higher, more preferably 180° C. or higher, and most preferably 200° C. or higher. If the 5%-weight loss temperature is lower than 150° C., the exfoliation is likely to occur due to the outgas during curing. Since the material design placing organic compounds as main ingredients is preferable from the viewpoint of the viscosity reduction of an adhesive composition, and the suppression of surface irregularities after application and the hot fluidity after film making, the 5%-weight loss temperature is preferably 500° C. or lower. In order to fall the 5%-weight loss temperature in such a range, the amount of a solvent contained in an adhesive composition is preferably 5% by mass or less, more preferably 3% by mass or less, and most preferably 1% by mass or less.

The 5%-weight loss temperature used here is a value measured as follows. An adhesive composition is applied on a silicon wafer by spin coating (2,000 rpm/10 sec, 4,000 rpm/20 sec); and a release-treated PET film is laminated on the obtained coating film at room temperature using a hand roller, and exposed to 1,000 mJ/cm² using a high-precision parallel exposure machine (“EXM-1172-B-∞” (trade name), made by ORC Manufacturing Co., Ltd.). Thereafter, the adhesive having been rendered into a B-stage is measured for the 5%-weight loss temperature using a simultaneous thermogravimetric/differential thermal analyzer (trade name “TG/DTA6300”, made by SII Nano Technology Inc.) at a temperature-rise rate of 10° C./min in a nitrogen flow (400 ml/min).

In the adhesive composition according to the present invention, the film formed by light irradiation preferably has a surface tack force at 30° C. of 200 gf/cm² or lower, and preferably a surface tack force at 120° C. of 200 gf/cm² or higher. In order to suppress chip scattering and the like in dicing, the surface tack force is preferably 0.1 gf/cm² or higher. If the surface tack force at 30° C. exceeds 200 gf/cm², the pressure-sensitive adhesivity of the surface at room temperature of an obtained adhesive layer becomes high, and the handleability is likely to worsen. Further, the following problems are liable to arise: chip scattering occurs due to infiltration of water into an interface between an adhesive and an adherend in dicing, and the delaminating property from a dicing sheet after dicing decreases and the pickup performance decreases, which are not preferable.

In order to make the surface tack force at 30° C. to be in the above, the amount of a solvent in an adhesive composition is preferably 5% or less, more preferably 3% or less, and most preferably 1% or less.

The surface tack force is a value measured as follows. An adhesive composition is applied on a PET (polyethylene terephthalate) film so that the coating film thickness becomes 30 μm; and a release-treated PET film is laminated on the obtained coating film, and exposed to 1,000 mJ/cm² using a high-precision parallel exposure machine (“EXM-1172-B-∞” (trade name), made by ORC Manufacturing Co., Ltd.). Thereafter, the surface tack forces at 30° C. and 120° C. are measured using a probe tacking tester made by Rhesca Corp., with a probe diameter of 5.1 mm, a peeling rate of 10 mm/sec, a contact load of 100 gf/cm² and a contact time of 1 sec.

In the adhesive composition according to the present invention, the film formed by light irradiation preferably has a minimum melt viscosity at 20° C. to 300° C. of 5,000 Pa·s or lower.

The minimum melt viscosity used here refers to a minimum value of the melt viscosities at 20° C. to 300° C. of a sample as measured using a viscoelastometer ARES (made by Rheometrics Scientific F.E. Ltd.), the sample being prepared by applying an adhesive composition on a PET (polyethylene terephthalate) film so that the coating film thickness becomes 30 μm, and in the air or after a base material is laminated thereon, exposing the applied composition to a light amount of 1,000 mJ/cm². Measurement plates used in the viscoelasticity measurement are parallel plates of 8 mm in diameter, and measurement conditions are set at a temperature-rise rate of 5° C./min, measurement temperatures of 20° C. to 300° C., and a frequency of 1 Hz.

In the adhesive composition according to the present invention, the film formed by light irradiation preferably has a storage elastic modulus at 100° C. of 0.1 MPa or lower. If the storage elastic modulus at 100° C. exceeds 0.1 MPa, it is likely that the low-temperature pastability and the thermocompression bondability are spoiled, and voids are generated during pasting time and thermocompression bonding time, and the thermocompression bonding temperature becomes high, which is not preferable.

The storage elastic modulus used here refers to a storage elastic modulus at 100° C. of a laminate-strip as measured using a viscoelasticity analyzer “RSA-2” (trade name), made by Rheometrics Scientific Inc., under the conditions of a temperature-rise rate of 5° C./min, a frequency of 1 Hz and measurement temperatures 0 to 300° C., the laminate-strip being prepared by applying an adhesive composition on a PET (polyethylene terephthalate) film so that the coating film thickness becomes 30 μm, and in the air or after a base material is laminated thereon, exposing the applied composition to a light amount of 1,000 mJ/cm² to obtain a sample, thereafter laminating the samples so that the laminate thickness becomes 150 μm by roll pressurization (temperature: 60° C., line pressure: 4 kgf/cm, feed rate: 0.5 m/min), and cutting the obtained laminate into a 5 mm-width strip.

The adhesive composition according to the present invention preferably has a 5%-weight loss temperature of 260° C. or higher after the composition is made into a film by light irradiation and further heat cured. If the 5%-weight loss temperature is lower than 260° C., exfoliation is likely to occur by the thermal history including a reflow step.

The outgas amount in heat curing is preferably 10% or less, more preferably 7% or less, and most preferably 5% or less. If the outgas amount exceeds 10%, voids and exfoliation are likely to occur in heat curing.

The outgas amount used here is a value of a 5%-weight loss temperature measured as follows. An adhesive composition is applied on PET (polyethylene terephthalate) film so that the coating film thickness becomes 30 μm; and a release-treated PET film is laminated on the obtained coating film at room temperature using a hand roller, and exposed to 1,000 mJ/cm² using a high-precision parallel exposure machine (“EXM-1172-B-∞” (trade name), made by ORC Manufacturing Co., Ltd.). Thereafter, the adhesive having been made into a film is measured for the 5%-weight loss temperature using a simultaneous thermogravimetric/differential thermal analyzer (trade name “TG/DTA6300”, made by SII Nano Technology Inc.) in a nitrogen flow (400 ml/min) under the program in which the temperature is raised to 140° C. at a temperature-rise rate of 50° C./min, held at 140° C. for 1 hour, further raised to 180° C. at a temperature-rise rate of 50° C./min, and held at 180° C. for 3 hours.

A film-like adhesive formed from the adhesive composition according to the present invention preferably has a shearing adhesive strength at 260° C., at the stage that a semiconductor element is adhered thereon, of 0.2 MPa or higher, and more preferably 0.5 MPa or higher. If the shearing adhesive strength is lower than 0.2 MPa, exfoliation is likely to occur by the thermal history including a reflow step.

The shearing adhesive strength used here is measured as follows. A silicon wafer having a film-like adhesive pasted thereon by roll pressurization (temperature: 60° C., line pressure: 4 kgf/cm, feed rate: 0.5 m/min) is prepared, and cut out into a 3×3-mm square. The cut-out silicon chip having the adhesive is mounted on a silicon chip previously cut out into a 5×5-mm square, and compression bonded at 120° C. for 2 sec under a pressurization of 200 gf. Thereafter, the resultant chip is heated at 140° C. for 1 hour, and then at 180° C. for 3 hours in an oven to thereby obtain an adhesive sample. The shearing adhesive force at 260° C. of the obtained sample is measured using a shearing adhesive force tester “Dage-4000” (trade name) (measurement condition: a speed of 50 μm/sec, and a height of 50 μm), and the result is defined as a value of a shearing adhesive strength.

The adhesive sheet according to the present invention includes one having a structure in which a dicing sheet and the film-like adhesive according to the present invention are laminated (for example, FIG. 3). Such an adhesive sheet can easily be obtained by using a dicing sheet as a base material in the method for manufacturing a film-like adhesive according to the present invention. In the present embodiment, the film-like adhesive is preferably previously formed (precut) into a shape similar to a wafer.

The adhesive sheet more specifically includes an adhesive sheet in which a base material film, a pressure-sensitive adhesive layer and the film-like adhesive according to the present invention are laminated in this order, and an adhesive sheet formed of a base material film and the film-like adhesive according to the present invention. This adhesive sheet, for the purpose of simplifying a step of manufacturing a semiconductor device, is an integrated adhesive sheet having, at least, a film-like adhesive, and a dicing sheet or a base material film capable of securing an elongation (so-called expansion) on impression of a tensile tension. That is, the adhesive sheet is one having both of properties required for both of a dicing sheet and a die bonding film.

In such manners, by providing a pressure-sensitive adhesive layer serving a function as a dicing sheet on a base material film, and further laminating the film-like adhesive according to the present invention serving a function as a die bonding film on the pressure-sensitive adhesive layer, or by laminating the above-mentioned expandable base material film and the film-like adhesive according to the present invention, a function as a dicing sheet can be exhibited in dicing; and a function as a die bonding film, in die bonding. Therefore, an integrated adhesive sheet is laminated on a wafer back surface while the film-like adhesive of the integrated adhesive sheet is being heated, and diced; and thereafter, semiconductor elements having the adhesive can be picked up and used.

The pressure-sensitive adhesive layer described above may be either of a pressure-sensitive type or a radiation-curing type; but the radiation-curing type is better from the viewpoint of exhibiting a high pressure-sensitive adhesive force in dicing, and exhibiting a low pressure-sensitive adhesive force by irradiation with ultraviolet rays (UV) before picking-up, thus bringing about easy control of the pressure-sensitive adhesive force. As the radiation-curable pressure-sensitive adhesive layer, conventionally well-known ones can be used without any especial limitation as long as having such a sufficient pressure-sensitive adhesive force that semiconductor elements do not scatter in dicing, and having such a low pressure-sensitive adhesive force that the semiconductor elements are not harmed in a pickup step of the semiconductor elements thereafter.

The base material film described above is not especially limited as long as being a film capable of securing an elongation (so-called expansion) on impression of a tensile tension, but a film whose material is a polyolefin is preferably used.

The film-like adhesive and the adhesive sheet according to the present invention can be used as adhesive materials for die bonding to laminate semiconductor elements such as ICs and LSIs with adherends of support members for mounting semiconductors and the like including lead frames such as 42 alloy lead frames and copper lead frames, plastic films such as of polyimide resins and epoxy resins, base materials of glass nonwoven fabrics impregnated with plastics such as polyimide resins and epoxy resins and cured, and ceramics such as alumina. The film-like adhesive and the adhesive sheet are suitably used particularly as adhesive materials for die bonding to adhere organic substrates having irregularities on the surface such as organic substrates equipped with an organic resist layer on the surface and organic substrates having wiring on the surface, with semiconductor elements.

The film-like adhesive and the adhesive sheet are suitably used also as adhesive materials to protect, fill and adhere semiconductor elements in Stacked PKGs having a structure in which a plurality of semiconductor elements are stacked.

Hereinafter, a semiconductor device manufactured using the adhesive sheet according to the present invention, and a method for manufacturing the same will be specifically described by way of drawings. In recent years, semiconductor devices having various types of structures have been proposed, and applications of the liquid adhesive composition for semiconductors according to the present invention are not limited to a semiconductor device having a structure described hereinafter, and a method for manufacturing the same.

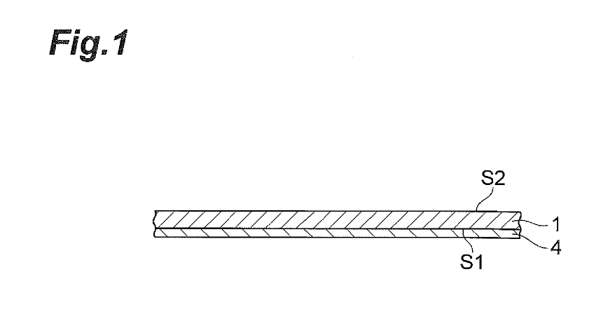

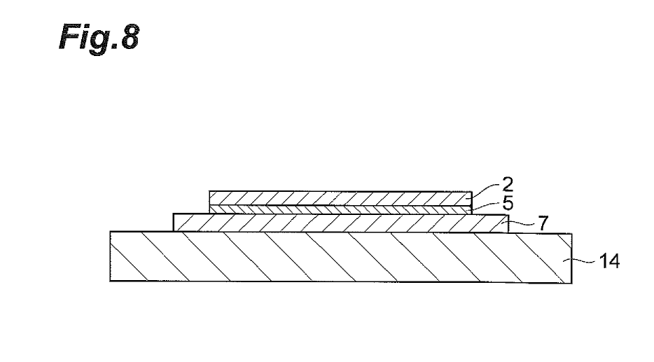

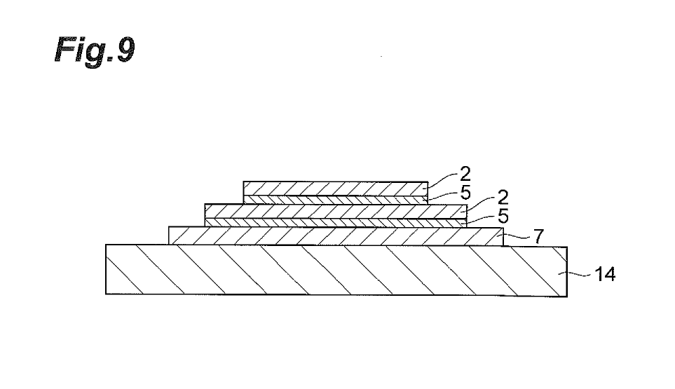

FIGS. 1 to 11 are illustrative diagrams showing one embodiment of a method for manufacturing a semiconductor device. The manufacturing method according to the present embodiment has the following steps.

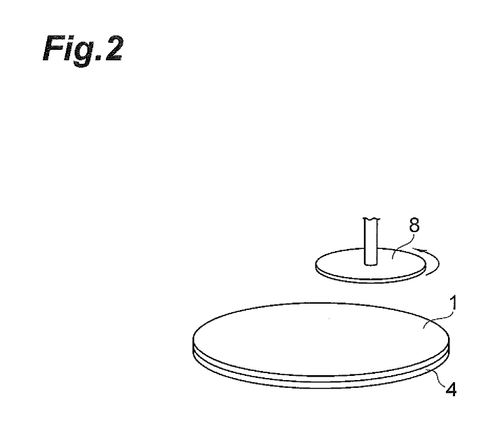

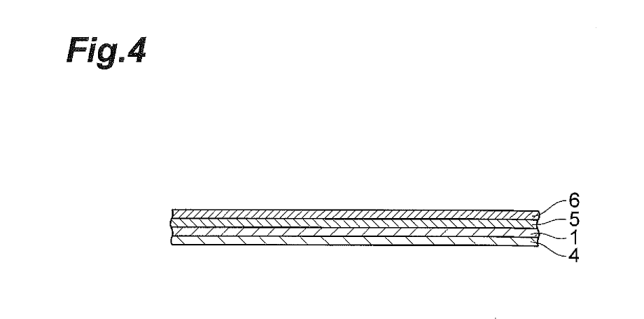

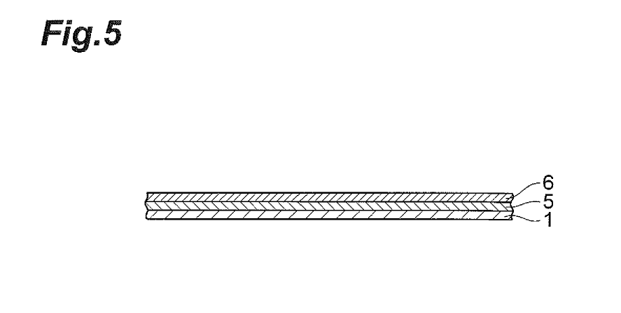

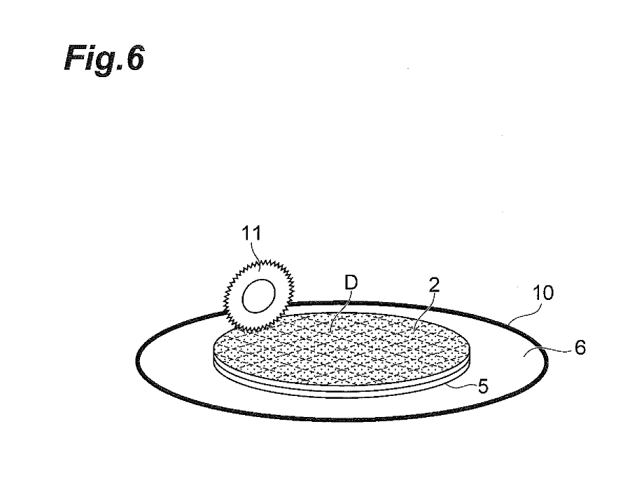

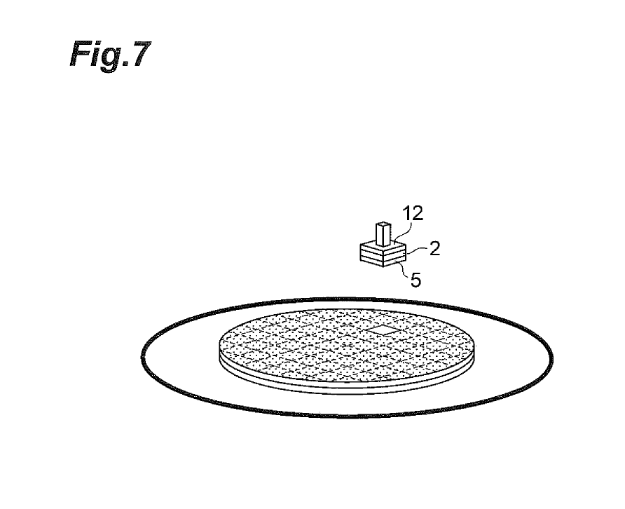

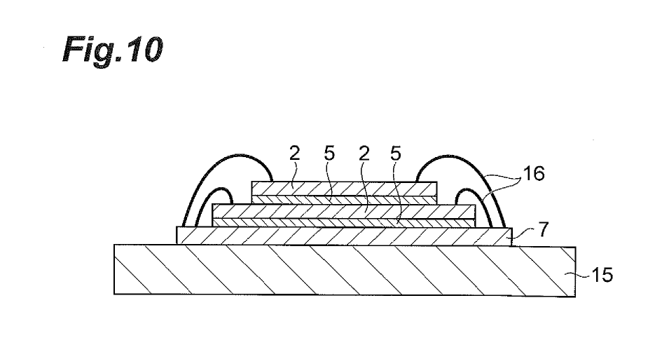

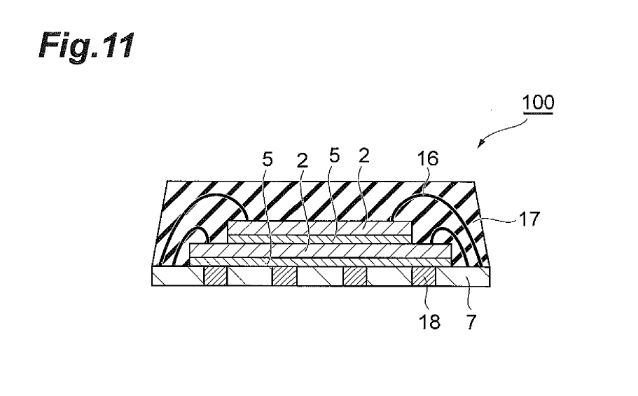

Step 1: a delaminatable pressure-sensitive adhesive tape (back grind tape) 4 is laminated on a circuit surface S1 of semiconductor chips (semiconductor elements) 2 formed in a semiconductor wafer 1 (see FIG. 1).
Step 2: the semiconductor wafer 1 is ground from the surface (back surface) S2 opposite to the circuit surface S1 to thin the semiconductor wafer 1 (see FIG. 2).
Step 3: the adhesive sheet 50 according to the present invention is prepared (see FIG. 3), and an adhesive layer 5 (film-like adhesive) of the adhesive sheet 50 according to the present invention is pasted on the surface S2 opposite to the circuit surface S1 of the semiconductor wafer 1 (see FIG. 4).
Step 4: the delaminatable pressure-sensitive adhesive tape 4 is delaminated (see FIG. 5).
Step 5: the semiconductor wafer 1 is cut and divided into a plurality of semiconductor chips (semiconductor elements) 2 by dicing (see FIG. 6).
Step 6: the semiconductor chip 2 is picked up and compression bonded (mounted) on a support member (support member for mounting a semiconductor element) 7 for a semiconductor device, or on a semiconductor chip (see FIGS. 7, 8 and 9).
Step 7: the mounted semiconductor chip is connected with external connection terminals on the support member 7 through wires 16 (see FIG. 10).
Step 8: a laminate containing the plurality of semiconductor chips 2 is sealed with a sealing material 17 to thereby obtain a semiconductor device 100 (see FIG. 11).

Hereinafter, (Step 1) to (Step 8) will be described in detail.

(Step 1)

A delaminatable pressure-sensitive adhesive tape 4 is laminated on the circuit surface S1 of a semiconductor wafer 1 having circuits formed on the surface thereof. The lamination of the pressure-sensitive adhesive tape 4 can be carried out by a method of laminating a film formed previously into a film-shape.

(Step 2)

The surface S2 of the opposite side to the pressure-sensitive adhesive tape 4 of the semiconductor wafer 1 is ground to thin the semiconductor wafer 1 to a predetermined thickness. The grinding is carried out using a grinding apparatus 8 in a state where the semiconductor wafer 1 is fixed to a jig for grinding through the pressure-sensitive adhesive tape 4.

(Step 3)

The adhesive sheet 50 can be fabricated by using a dicing sheet as a base material in the above-mentioned manufacturing method of a film-like adhesive according to the present invention.

A method for pasting the adhesive layer 5 of the adhesive sheet 50 on the back surface of the semiconductor wafer 1 includes roll lamination.

(Step 4)

Then, the pressure-sensitive adhesive tape 4 pasted on the circuit surface of the semiconductor wafer 1 is delaminated. For example, the pressure-sensitive adhesive tape is used whose pressure-sensitive adhesivity decreases by irradiation with active light rays (typically, ultraviolet rays), and after the wafer is exposed from the pressure-sensitive adhesive tape 4 side, the pressure-sensitive adhesive tape 4 can be delaminated.

(Step 5)

The semiconductor wafer 1 is cut together with the adhesive layer 5 along dicing lines D. This dicing cuts and divides the semiconductor wafer 1 into a plurality of semiconductor chips 2 each having the adhesive layer 5 on the back surface thereof. The dicing is carried out by using a dicing blade 11 in a state where the whole is fixed on a frame (wafer ring) 10 with a pressure-sensitive adhesive tape (dicing tape) 6.

(Step 6)

After the dicing, the cut and divided semiconductor chip 2 is picked up together with the adhesive layer 5 by a die bonding apparatus 12, that is, the semiconductor element having the adhesive layer is picked up, and compression bonded (mounted) on a support member (support member for mounting a semiconductor element) for a semiconductor device, or on another semiconductor chip 2. The compression bonding is carried out preferably under heating. The heating temperature is usually 20 to 250° C.; the load is usually 0.01 to 20 kgf; and the heating time is usually 0.1 to 300 sec.

The shearing adhesive strength at 260° C. between the semiconductor chip and the support member or the another semiconductor chip is preferably 0.2 MPa or higher, and more preferably 0.5 MPa or higher, from the viewpoint of suppressing delamination due to the thermal history, and from the viewpoint of the moisture absorption reflow resistance, most preferably 1.0 MPa or higher. On the other hand, the shearing adhesive strength is preferably 50 MPa or lower. The measurement of the shearing adhesive strength can be carried out as described above.

(Step 7)

After Step 6, the each semiconductor chip 2 is connected to external connection terminals on the support member 7 through wires 16 connected to bonding pads of the semiconductor chip 2.

(Step 8)

The laminate containing the semiconductor chip 2 is sealed with the sealing material 17 to thereby obtain a semiconductor device 100. As the sealing material at this time, the film-like adhesive according to the present invention may be used. Specifically, the film-like adhesive according to the present invention is laminated on the laminate, and heat cured for sealing. Alternatively, dicing is carried out after sealing is carried out collectively, and the package may be individualized into pieces.

Through the steps as described above, a semiconductor device can be manufactured which has a structure in which semiconductor elements, and/or a semiconductor element and a support member for mounting a semiconductor element are adhered using the film-like adhesive according to the present invention. The constitution and the manufacturing method of the semiconductor device are not limited to the embodiment described above, and suitable changes and modifications may be possible without departing from the gist of the present invention.

For example, the order of Steps 1 to 7 can be exchanged as required. More specifically, the film-like adhesive according to the present invention may be pasted on the back surface of a semiconductor wafer previously diced.

### EXAMPLES

Hereinafter, the present invention will be described more specifically by way of Examples. However, the present invention is not limited to the following Examples.

<(F) Component: Preparation of Thermoplastic Resins>

### (P-1)

80 g of dimethylformamide and 20 g of N-acryloyloxyethylhexahydrophthalimide were weighed in a four-necked flask, and stirred; and thereafter, 0.6 g of 2,2′-azobisisobutyronitrile was added and dissolved. Thereafter, the solution was held at 60° C. for 3 hours, held at 90° C. for 1 hour, and naturally cooled to obtain a solution of an acryl polymer. Then, the solution was three times subjected to a reprecipitation with a methanol/THF solution to obtain a white solid (P-1) of the acryl polymer. The acryl polymer (P-1) was subjected to a GPC measurement, and revealed to have a weight-average molecular weight (Mw) of 40,000 in terms of polystyrene. Tg of (P-1) was 70° C.

### (P-2)

5.72 g (0.02 mol) of 5,5′-methylenebis(anthranylic acid) (molecular weight: 286.3)(hereinafter, abbreviated to “MBAA”), 13.57 g (0.03 mol) of a polyoxypropylenediamine (trade name “D-400” (molecular weight: 452.4), made by BASF AG) and 2.48 g (0.01 mol) of 1,1,3,3-tetramethyl-bis(3-aminopropyl)disiloxane (trade name “BY16-871EG”, made by Dow Corning Toray Co., Ltd.) as diamines, and 115 g of NMP (N-methyl-2-pyrrolidone) as a solvent were charged in a 300-mL flask equipped with a stirrer, a thermometer and a nitrogen-purging apparatus (nitrogen inflow tube), and stirred to dissolve the diamines in the solvent.

29.35 g (0.09 mol) of 4,4′-oxydiphthalic dianhydride (hereinafter, abbreviated to “ODPA”) and 3.84 g (0.02 mol) of TAA (trimellitic acid anhydride) were added little by little in the solution in the flask under cooling in ice bath. After the completion of the addition, the solution was stirred at room temperature for 5 hours. Thereafter, a reflux cooler with a moisture receiving vessel was attached to the flask; the solution was heated to and held at 180° C. for 5 hours while a nitrogen gas was being blown in to remove the moisture to thereby obtain a polyimide resin (P-2). The polyimide resin (P-2) was subjected to a GPC measurement, and revealed to have a weight-average molecular weight (Mw) of 21,000 in terms of polystyrene. Tg of (P-2) was 55° C.

<Preparation of Adhesive Compositions>

Using the thermoplastic resins (P-1) and (P-2) obtained in the above, each component was blended in compositional ratios (unit: parts by mass) shown in the following Tables 1 to 3 to thereby obtain adhesive compositions of Examples 1 to 13 and adhesive compositions (vanishes for forming an adhesive layer) of Comparative Examples 1 and 2.

In Tables 1 to 3, each symbol means the following.

M-140: N-acryloyloxyethylhexahydrophthalamide (5%-weight loss temperature: 200° C., viscosity at 25° C.: 450 mPa·s), made by Toagosei Co., Ltd.
702A: 2-hydroxy-3-phenoxypropyl acrylate (5%-weight loss temperature: 175° C., viscosity at 25° C.: 160 mPa·s), made by Shin-Nakamura Chemical Co., Ltd.
A-BPE4: ethoxylated bisphenol A acrylate (5%-weight loss temperature: 330° C., viscosity at 25° C.: 950 mPa·s), made by Shin-Nakamura Chemical Co., Ltd.
I-651: 2,2-dimethoxy-1,2-diphenylethan-1-one (5%-weight loss temperature: 170° C., i-line extinction coefficient: 400 ml/g·cm), made by Ciba Japan K.K.

### I-379EG:

2-dimethylamino-2-(4-methyl-benzyl)-1-(4-morpholin-4-yl-phenyl)-but an-1-one (5%-weight loss temperature: 260° C., molecular extinction coefficient at 365 nm: 8,000 ml/g·cm), made by Ciba Japan K.K.
I-907: 2-methyl-1-(4-(methylthio)phenyl)-2-morpholinopropan-1-one (5%-weight loss temperature: 220° C., molecular extinction coefficient at 365 nm: 450 ml/g·cm), made by Ciba Japan K.K.
I-OXE02: ethanone, 1-[9-ethyl-6-(2-methylbenzoyl)-9H-carbazol-3-yl]-, 1-(o-acetyloxime) (5%-weight loss temperature: 370° C., molecular extinction coefficient at 365 nm: 7,700 ml/g·cm), made by Ciba Japan K.K.
YDF-8170C: a bisphenol F bisglycidyl ether (5%-weight loss temperature: 270° C., viscosity at 25° C.: 1,300 mPa·s), made by Tohto Kasei Co., Ltd.
1032H60: a tris(hydroxyphenyl)methane-type solid epoxy resin (5%-weight loss temperature: 350° C., solid, melting point: 60° C.), made by Japan Epoxy Resins Co., Ltd.
MEH-8000H: a modified liquid phenol novolac resin (5%-weight loss temperature: 220° C., viscosity: 2,500 mPa·s), made by Meiwa Plastic Industries Ltd.
2PHZ-PW: 2-phenyl-4,5-dihydroxymethylimidazole (average particle diameter: about 3 μm), made by Shikoku Chemicals Corp.
1B2PZ: 1-benzyl-2-phenylimidazole, made by Shikoku Chemicals Corp.
Percumyl D: dicumyl peroxide (one-minute half-life temperature: 175° C.), made by NOF Corp.
NMP: N-methyl-2-pyrrolidone, made by Kanto Chemical Co., Inc.

The 5%-weight loss temperature of the sample was measured using a simultaneous thermogravimetric/differential thermal analyzer (trade name “TG/DTA6300”, made by SII Nano Technology Inc.) at temperature-rise rate of 10° C./min in a nitrogen flow (400 ml/min).

The viscosity was a value measured using an EHD-type rotary viscometer made by Tokyo Keiki Inc., under the conditions of a sample amount of 0.4 mL, and a 3° cone at 25° C.

The molecular extinction coefficient was determined by preparing a 0.001-mass % acetonitrile solution of a sample, placing the solution in a quartz cell, and measuring an extinction using a spectrophotometer (“U-3310” (trade name), made by Hitachi High-Technologies Corp.) at room temperature (25° C.) in the air.

TABLE 1

| | | Example 1 | Example 2 | Example 3 | Example 4 | Example 5 | Example 6 | Example 7 |
|---|---|---|---|---|---|---|---|---|
| (A) Radiation-Polymerizable | M-140 | — | 80 | 80 | 80 | 80 | 80 | 80 |
| Compound | 702A | — | — | — | — | — | — | — |
| | A-BPE4 | 40 | — | — | — | — | — | — |
| (B) Photoinitiator | I-651 | — | — | 3 | 9 | — | — | — |
| | I-379EG | 3 | 3 | — | — | 3 | — | — |
| | I-907 | — | — | — | — | — | 3 | — |
| | I-OXE02 | — | — | — | — | — | — | 3 |
| (C) Thermosetting Resin | YDF-8170C | 20 | 20 | 20 | 20 | 20 | 20 | 20 |
| | 1032H60 | — | — | — | — | — | — | — |
| (D) Curing Agent | MEH-8000H | — | — | — | — | — | — | — |
| | 2PHZ-PW | — | — | — | — | — | — | — |
| | 1B2PZ | 1 | 1 | 1 | 1 | 1 | 1 | 1 |
| (E) Thermoradical Generator | Percumyl D | 1 | 1 | 1 | 1 | 1 | 1 | 1 |
| (F) Thermoplastic Resin | P-1 | 20 | — | — | — | — | — | — |
| | P-2 | — | 20 | — | — | — | — | — |

| | | | | | | | |
|---|---|---|---|---|---|---|---|
| Viscosity at 25° C. of Adhesive Composition | 8000 | 3200 | 600 | 700 | 600 | 600 | 650 |
| (mPa · s) | | | | | | | |
| Formability of Film by Light Irradiation | A | A | A | A | A | A | A |
| Film Thickness (μm) | 30 | 30 | 30 | 30 | 30 | 30 | 30 |
| Tack at 30° C. after Light Irradiation (gf) | 10 | 15 | 15 | 15 | 10 | 15 | 10 |
| Tack at 30° C. after Light Irradiation in the | 20 | 30 | >200 | 20 | 20 | 30 | 120 |
| Air (gf) | | | | | | | |
| Required-Smallest Light Amount for Film making | 100 | 100 | >1000 | 200 | 100 | 200 | 500 |
| (mJ/cm²) | | | | | | | |
| Required-Shortest Time for Film making (sec) | 10 | 10 | >100 | 20 | 10 | 20 | 50 |
| Melt Viscosity (mPa · s) | 1400 | <1000 | <1000 | <1000 | <1000 | <1000 | <1000 |
| Low-Temperature Pastability | A | A | A | A | A | A | A |
| Thermocompression Bondability | A | A | A | A | A | A | A |
| 5%-Weight Loss Temperature after Light | 260 | 260 | 260 | 200 | 240 | 230 | 240 |
| Irradiation (° C.) | | | | | | | |
| Adhesive Strength at 260° C. (MPa) | 1.2 | 1.8 | 1.4 | 0.7 | 1.2 | 1.0 | 1.1 |

TABLE 2

| | | Example 8 | Example 9 | Example 10 | Example 11 | Example 12 | Example 13 |
|---|---|---|---|---|---|---|---|
| (A) Radiation-Polymerizable | M-140 | 80 | 80 | — | 80 | 60 | 80 |
| Compound | 702A | — | — | 80 | — | — | — |
| | A-BPE4 | — | — | — | — | 20 | — |
| (B) Photoinitiator | I-651 | — | — | — | — | — | — |
| | I-379EG | 3 | 3 | 3 | 3 | 3 | 3 |
| | I-907 | — | — | — | — | — | — |
| | I-OXE02 | — | — | — | — | — | — |
| (C) Thermosetting Resin | YDF-8170C | 20 | 20 | — | — | — | — |
| | 1032H60 | — | — | 20 | 20 | 40 | 40 |
| (D) Curing Agent | MEH-8000H | 5 | — | — | — | — | — |
| | 2PHZ-PW | — | 1 | — | — | — | — |
| | 1B2PZ | 1 | — | 1 | 1 | 1 | 1 |
| (E) Thermoradical Generator | Percumyl D | 1 | 1 | 1 | 1 | 1 | 1 |
| (F) Thermoplastic Resin | P-1 | — | — | — | — | 20 | 20 |
| | P-2 | — | — | — | — | — | — |

| | | | | | | |
|---|---|---|---|---|---|---|
| Viscosity at 25° C. of Adhesive Composition | 750 | 650 | 500 | 1200 | 5000 | 12000 |
| (mPa · s) | | | | | | |
| Formability of Film by Light Irradiation | A | A | A | A | A | A |
| Film Thickness (μm) | 30 | 30 | 30 | 30 | 50 | 200 |
| Tack at 30° C. after Light Irradiation (gf) | 20 | 10 | 20 | 10 | 10 | 10 |
| Tack at 30° C. after Light Irradiation in the | 40 | 20 | 30 | 10 | 10 | 10 |
| Air (gf) | | | | | | |
| Required-Smallest Light Amount for Film making | 200 | 100 | 100 | 100 | 100 | 100 |
| (mJ/cm²) | | | | | | |
| Required-Shortest Time for Film making (sec) | 20 | 10 | 10 | 10 | 10 | 10 |
| Melt Viscosity (mPa · s) | <1000 | <1000 | <1000 | <1000 | 1200 | <1000 |
| Low-Temperature Pastability | A | A | A | A | A | A |
| Thermocompression Bondability | A | A | A | A | A | A |
| 5%-Weight Loss Temperature after Light | 220 | 240 | 210 | 280 | 280 | 280 |
| Irradiation (° C.) | | | | | | |
| Adhesive Strength at 260° C. (MPa) | 0.7 | 0.9 | 1.0 | 1.8 | 1.9 | 2.8 |

TABLE 3

| | | Comparative | Comparative |
|---|---|---|---|
| | | Example 1 | Example 2 |
| (A) Radiation- | M-140 | 80 | — |
| Polymerizable | | | |
| Compound | | | |
| (B) Photoinitiator | I-379EG | 3 | 3 |
| (C) Thermosetting Resin | YDF-8170C | 20 | 20 |
| (D) Curing Agent | 1B2PZ | 1 | 1 |
| (E) Thermoradical | Percumyl D | 1 | — |
| Generator | | | |
| (F) Thermoplastic Resin | P-1 | 20 | — |
| | P-2 | — | 10 |
| Organic Solvent | NMP | 50 | — |

| | | |
|---|---|---|
| Formability of Film by Light Irradiation | C | C |
| Film Thickness (μm) | unmeasurable | unmeasurable |
| Tack at 30° C. after Light Irradiation | unmeasurable | unmeasurable |
| (gf) | | |
| Tack after Light Irradiation in the Air | unmeasurable | unmeasurable |
| (gf) | | |
| 5%-Weight Loss Temperature after | 120 | 260 |
| Light Irradiation (° C.) | | |
| Adhesive Strength at 260° C. (MPa) | unmeasurable | unmeasurable |

For each of the adhesive compositions obtained in the above, the viscosity thereof, the formability of the film by light irradiation, the film thickness, the tack after light irradiation, the tack after light irradiation in the air, the required-smallest light amount for film making, the required-shortest time for film making, the melt viscosity, the thermocompression bondability, the 5%-weight loss temperature after light irradiation, and the adhesive strength at 260° C. were evaluated according to the following methods.

<Viscosity>

The viscosity at 25° C. was measured using an EHD-type rotary viscometer, made by Tokyo Keiki Inc.

<Film Formability by Light Irradiation>

An adhesive composition was applied on a polyethylene terephthalate (PET) film using an applicator so that the coating film thickness became a predetermined thickness. A release-treated PET film was laminated on the obtained coating film using a hand roller, and thereafter exposed to 1,000 mJ/cm² using a high-precision parallel exposure machine (“EXM-1172-B-∞” (trade name), made by ORC Manufacturing Co., Ltd., intensity: 10 mW/cm²). The obtained adhesive layer having a predetermined film thickness was delaminated from the polyethylene terephthalate (PET) film; and a case where a film-like structure could be obtained as a single material was evaluated as A, and a case where that could not be obtained was evaluated as C.

<Film Thickness>

The thickness of an adhesive layer was measured using a surface roughness tester (made by Kosaka Laboratory Ltd.).

<Tack (Surface Tack Force) after Light Irradiation>

An adhesive composition was applied on a polyethylene terephthalate (PET) film using an applicator so that the coating film thickness became a predetermined thickness. A release-treated PET film was laminated on the obtained coating film using a hand roller, and thereafter exposed to 1,000 mJ/cm² using a high-precision parallel exposure machine (“EXM-1172-B-∞” (trade name), made by ORC Manufacturing Co., Ltd., intensity: 10 mW/cm²). Thereafter, the surface tack forces at 30° C. were measured five times using a probe tacking tester made by Rhesca Corp., with a probe diameter of 5.1 mm, a peeling rate of 10 mm/sec, a contact load of 100 gf/cm² and a contact time of 1 sec, and the average value was calculated.

<Tack (Surface Tack Force) after Light Irradiation in the Air>

An adhesive composition was applied on a polyethylene terephthalate (PET) film using an applicator so that the coating film thickness became a predetermined thickness. The obtained coating film was exposed to 1,000 mJ/cm² using a high-precision exposure parallel machine (“EXM-1172-B-∞” (trade name), made by ORC Manufacturing Co., Ltd., intensity: 10 mW/cm²) at room temperature in the air. Thereafter, the surface tack forces at 30° C. were measured five times using a probe tacking tester made by Rhesca Corp., with a probe diameter of 5.1 mm, a peeling rate of 10 mm/sec, a contact load of 100 gf/cm² and a contact time of 1 sec, and the average value was calculated.

<Required-Smallest Light Amount for Film Making and the Required-Shortest Time for B-Stage Formation>

An adhesive composition was applied on a polyethylene terephthalate (PET) film using an applicator so that the coating film thickness became 30 μm. The obtained coating films were exposed, respectively, to 100, 200, 500 and 1,000 mJ/cm² using a high-precision parallel exposure machine (“EXM-1172-B-∞” (trade name), made by ORC Manufacturing Co., Ltd., intensity: 10 mW/cm²), at room temperature in the air for Examples 1 and 2 and Examples 4 to 14, and at room temperature in the air after a release-treated PET film was laminated on the obtained coating film for Example 3. After the exposure to the predetermined amount, an exposure amount at which the surface tack force at 30° C. measured by the method described above became 200 gf/cm² or lower was defined as a required-smallest light amount for film making (mJ/cm²). Further, a required time at this time was defined as a required-shortest time for film making (sec).

<Melt Viscosity>

The melt viscosity used here was a value measured as follows. An adhesive composition was applied on a PET film so that the coating film thickness became 50 μm. The obtained coating film was exposed to 1,000 mJ/cm² using a high-precision parallel exposure machine (“EXM-1172-B-∞” (trade name), made by ORC Manufacturing Co., Ltd.), at room temperature in the air for Examples 1 and 2 and Examples 4 to 14, and at room temperature in the air after a release-treated PET film was laminated on the obtained coating film for Example 3. The obtained adhesive sheet was laminated on a Teflon sheet under pressurization by a roll (temperature: 60° C., line pressure: 4 kgf/cm, feed rate: 0.5 m/min) with the adhesive layer on the Teflon sheet side so that the thickness became about 200 μm. The obtained sample was measured using a viscoelastometer (trade name: ARES, made by Rheometrics Scientific F.E. Ltd.). Measurement plates used in the viscoelasticity measurement were parallel plates of 25 mm in diameter, and measurement conditions were set at a temperature-rise rate of 10° C./min, and a frequency of 1 Hz. The lowest value of the melt viscosities at 20° C. to 200° C. was defined as a melt viscosity.

<Low-Temperature Pastability>

A silicon wafer (6-inch diameter, 400-μm thickness) was mounted on a support pedestal, and an adhesive layer fabricated by the same method as in the <film formability by light irradiation> was laminated on the wafer with the adhesive layer in contact with the back surface (surface opposite to the support pedestal) of the silicon wafer by roll pressurization (temperature: 80° C., line pressure: 4 kgf/cm, feed rate: 0.5 m/min). The base material (PET film) was delaminated and removed, and thereafter, a polyimide film (“UPILEX” (trade name), made by UBE Industries, Ltd.) of 80 μm thick, 10 mm wide and 40 mm long was laminated on the bare adhesive layer by roll pressurization of the same condition as the above. In such a manner, a sample of a laminate composed of the silicon wafer, the adhesive layer and the polyimide film laminated in this order was obtained.

The obtained sample was subjected to a 90° peel test at room temperature using a rheometer (“Strograph E-S” (trade name), made by Toyo Seiki Seisaku-sho, Ltd.), and the peel strength between the adhesive layer and the polyimide film was measured. Based on the measurement results, the pastability was evaluated such that a sample having a peel strength of 2 N/cm or higher was evaluated as A; and a sample of lower than 2 N/cm, as C.

<Thermocompression Bondability>

A silicon wafer (6-inch diameter, 400-μm thickness) was mounted on a support pedestal, and an adhesive layer fabricated by the same method as in the <film formability by light irradiation> was laminated on the wafer with the adhesive layer in contact with the back surface (surface opposite to the support pedestal) of the silicon wafer by roll pressurization (temperature: 80° C., line pressure: 4 kgf/cm, feed rate: 0.5 m/min). The base material (PET film) was delaminated and removed, and thereafter, the silicon wafer was cut out into a 3×3-mm square. The cut-out silicon chip having the adhesive was mounted on a silicon chip previously cut out into a 5×5-mm square, and thermocompression bonded at 120° C. for 2 sec under a pressurization of 200 gf. The obtained sample was measured for the adhesive force at room temperature using a shearing adhesive force tester “Dage-4000” (trade name) (measurement condition: a speed of 50 μm/sec, and a height of 50 μm); and the thermocompression bondability was evaluated such that a case where the adhesive force was 1 MPa or higher was evaluated as A; and a case where that of lower than 1 MPa, as C.

<5%-Weight Loss Temperature after Light Irradiation>

An adhesive composition was applied on a polyethylene terephthalate (PET) film using an applicator so that the coating film thickness became a predetermined thickness. A release-treated PET film was laminated on the obtained coating film, and thereafter was exposed to 1,000 mJ/cm² using a high-precision parallel exposure machine (“EXM-1172-B-∞” (trade name), made by ORC Manufacturing Co., Ltd., intensity: 10 mW/cm²). Thereafter, the obtained film-like adhesive was measured for the 5%-weight loss temperature using a simultaneous thermogravimetric/differential thermal analyzer (trade name “TG/DTA6300”, made by SII Nano Technology Inc.) at temperature-rise rate of 10° C./min in a nitrogen flow (400 ml/min).

<Adhesive Strength at 260° C.>

A silicon wafer (6-inch diameter, 400-μm thickness) was mounted on a support pedestal, and an adhesive layer fabricated by the same method as in the <film formability by light irradiation> was laminated on the wafer with the adhesive layer in contact with the back surface (surface opposite to the support pedestal) of the silicon wafer by roll pressurization (temperature: 80° C., line pressure: 4 kgf/cm, feed rate: 0.5 m/min). The base material (PET film) was delaminated and removed, and thereafter, the silicon wafer was cut out into a 3×3-mm square. The cut-out silicon chip having the adhesive was mounted on a silicon chip previously cut out into a 5×5-mm square, and thermocompression bonded at 120° C. for 2 sec under a pressurization of 200 gf. The obtained sample was measured for the adhesive force at 260° C. using a shearing adhesive force tester “Dage-4000” (trade name) (measurement condition: a speed of 50 μm/sec, and a height of 50 μm). The adhesive force was defined as an adhesive strength at 260° C.

### REFERENCE SIGNS LIST

1 . . . SEMICONDUCTOR WAFER, 2 . . . SEMICONDUCTOR CHIP, 4 . . . PRESSURE-SENSITIVE ADHESIVE TAPE (BACK GRIND TAPE), 5 . . . ADHESIVE LAYER (FILM-LIKE ADHESIVE), 6 . . . DICING TAPE, 7 . . . SUPPORT MEMBER, 8 . . . GRIND APPARATUS, 9 . . . EXPOSURE APPARATUS, 10 . . . WAFER RING, 11 . . . DICING BLADE, 12 . . . DIE BONDING APPARATUS, 14, 15 . . . HOT PLATE, 16 . . . WIRE, 17 . . . SEALING MATERIAL, 18 . . . CONNECTION TERMINAL, 50 . . . ADHESIVE SHEET, 100 . . . SEMICONDUCTOR DEVICE, S1 . . . CIRCUIT SURFACE OF SEMICONDUCTOR WAFER, and S2 . . . BACK SURFACE OF SEMICONDUCTOR WAFER

1. A method for manufacturing a film-like adhesive, comprising:
applying an adhesive composition comprising (A) a radiation-polymerizable compound, (B) a photoinitiator and (C) a thermosetting resin, and having a solvent content of 5% by mass or lower and being liquid at 25° C., on a base material to thereby form an adhesive composition layer; and irradiating the adhesive composition layer with light to thereby form the film-like adhesive.

2. The method for manufacturing a film-like adhesive according to claim 1, wherein the (A) component is liquid at 25° C.

3. The method for manufacturing a film-like adhesive according to claim 1, wherein the (A) component comprises a monofunctional (meth)acrylate being liquid at 25° C.

4. The method for manufacturing a film-like adhesive according to claim 3, wherein the monofunctional (meth)acrylate has an imide skeleton or a hydroxyl group.

5. The method for manufacturing a film-like adhesive according to claim 1, wherein the (B) component comprises a photoinitiator having a molecular extinction coefficient for light of a wavelength of 365 nm of 100 ml/g·cm or higher.

6. The method for manufacturing a film-like adhesive according to claim 5, wherein the photoinitiator having a molecular extinction coefficient for light of a wavelength of 365 nm of 100 ml/g·cm or higher is a compound having an oxime ester skeleton or a morpholine skeleton in a molecule thereof.

7. The method for manufacturing a film-like adhesive according to claim 1, wherein the adhesive composition further comprises (D) a curing agent.

8. The method for manufacturing a film-like adhesive according to claim 1, wherein the adhesive composition further comprises (E) a thermoradical generator.

9. An adhesive sheet, having a structure made by laminating a dicing sheet, and a film-like adhesive obtained by the method according to claim 1.

10. The adhesive sheet according to claim 9, wherein the dicing sheet comprises a base material film, and a radiation-curable pressure-sensitive adhesive layer provided on the base material film; and
the film-like adhesive has a structure made by laminating the radiation-curable pressure-sensitive adhesive layer.

11. The adhesive sheet according to claim 9, wherein the dicing sheet is composed only of a base material film.

12. A semiconductor device, having a structure made by adhering semiconductor elements and/or a semiconductor element and a support member for mounting a semiconductor element with a film-like adhesive obtained by the method according to claim 1.

13. A method for manufacturing a semiconductor device, comprising:
a step of pasting the film-like adhesive layer of the adhesive sheet according to claim 9 on one surface of a semiconductor wafer;
a step of cutting the semiconductor wafer along with the film-like adhesive layer to obtain a semiconductor element having the adhesive layer; and
a step of compression bonding and thereby adhering the semiconductor element having the adhesive layer with another semiconductor element or a support member for mounting a semiconductor element, with the adhesive layer of the semiconductor element having the adhesive layer interposed therebetween.

14. The method for manufacturing a film-like adhesive according to claim 7, wherein the adhesive composition further comprises (E) a thermoradical generator.
